(19) United States
(12) Patent Application Publication
(10) Pub. No.: US 2018/0295303 A1
(43) Pub. Date: Oct. 11, 2018

(54) IMAGING ELEMENT

(71) Applicant: Renesas Electronics Corporation, Tokyo (JP)

(72) Inventor: Fumihide MURAO, Tokyo (JP)

(73) Assignee: Renesas Electronics Corporation, Tokyo (JP)

(21) Appl. No.: 15/904,610

(22) Filed: Feb. 26, 2018

(30) Foreign Application Priority Data
Apr. 7, 2017 (JP) 2017-076926

(51) Int. Cl. H04N 5/363; H04N 5/353; H04N 5/374; H01L 27/146

(52) U.S. Cl. CPC H04N 5/363; H04N 5/3532; H01L 27/14636; H01L 27/14634; H01L 27/14612; H04N 5/374

(57) ABSTRACT

According to an embodiment, an imaging element includes a first chip in which a light detection circuit that amplifies a voltage level corresponding to an amount of light received by a photoelectric conversion element using a first source follower circuit and outputs a first imaging signal voltage is formed so as to be exposed to light and a second chip on which the first chip is stacked to shield a circuit formation region from light. In the circuit formation region of the second chip, at least a pixel value storage capacitance, an input transfer transistor which transfers the first imaging signal voltage output from the light detection circuit to the pixel value storage capacitance, and a second source follower circuit which amplifies a voltage generated on the basis of the first imaging signal voltage stored in the pixel value storage capacitance and outputs a second imaging signal voltage are formed.

### CROSS-REFERENCE TO RELATED APPLICATIONS

The disclosure of Japanese Patent Application No. 2017-076926 filed on Apr. 7, 2017 including the specification, drawings and abstract is incorporated herein by reference in its entirety.

### BACKGROUND

The present invention relates to an imaging element having a structure in which, e.g., a plurality of chips are stacked.

In an imaging element which converts light information to image data in a camera or the like, photoelectric conversion elements are arranged in a grid-like configuration. The image sensing element uses, as a shutter mode, a rolling shutter mode or a global shutter mode. In the rolling shutter mode, exposure and readout of an imaging signal are performed at timings shifted on a line-by-line basis. In the rolling shutter method, imaging is performed on a per line basis. Accordingly, when an object moving at a high speed is imaged, rolling distortion such that an image diagonally skews occurs. On the other hand, in the global shutter mode, exposure is simultaneously performed on all the photoelectric conversion elements, and readout of imaging signals resulting from the exposure process is performed. As a result, in the global shutter mode, the rolling distortion does not occur. Patent Document 1 discloses an example of an imaging element using the global shutter mode.

The solid-state imaging device described in Patent Document has a configuration in which a first substrate where a photoelectric conversion unit is formed and a second substrate where a charge storage capacitance portion and a plurality of MOS transistors are formed are bonded together. In the first substrate and the second substrate, respective coupling electrodes are formed to electrically couple the first substrate and the second substrate to each other. This allows the solid-state imaging device described in Patent Document 1, which has a global shutter function, to be formed to occupy a smaller area.

### RELATED ART DOCUMENT

### Patent Document

[Patent Document 1] Japanese Patent No. 4835710

However, the imaging element described in Patent Document 1 has a problem in that, in the process of retrieving an imaging signal from the photoelectric conversion unit and converting the imaging signal to image data, the potential in the imaging signal becomes unstable or, due to superimposed noise or the like, the image quality of the obtained image data deteriorates.

Other problems and novel features of the present invention will become apparent from a statement in the present specification and the accompanying drawings.

According to an embodiment, an imaging element includes a first chip in which a light detection circuit that amplifies a voltage level corresponding to an amount of light received by a photoelectric conversion element using a first source follower circuit and outputs a first imaging signal is formed so as to be exposed to light and a second chip on which the first chip is stacked to shield a circuit formation region from light. In the circuit formation region of the second chip, at least a pixel value storage capacitance, an input transfer transistor which transfers the first imaging signal output from the light detection circuit to the pixel value storage capacitance, and a second source follower circuit which amplifies a voltage generated on the basis of the first imaging signal stored in the pixel value storage capacitance and outputs a second imaging signal are formed.

According to the embodiment, a pixel value having a high S/N ratio can be obtained by reducing noise superimposed on a pixel value generated on the basis of the voltage level corresponding to the amount of light received by the photoelectric conversion element.

### BRIEF DESCRIPTION OF THE DRAWINGS

FIG. 1 is a block diagram of a camera system including an imaging element according to Embodiment 1;

FIG. 2 is a schematic diagram of a floor layout of the imaging element according to Embodiment 1;

FIG. 3 is a circuit diagram illustrating a light detection circuit and a pixel value storage circuit in the imaging element according Embodiment 1;

FIG. 4 is a timing chart illustrating the operations of the light detection circuit and the pixel value storage circuit in the imaging element according Embodiment 1;

FIG. 5 is a view illustrating charge transfer in the imaging element according Embodiment 1;

FIG. 6 is a view illustrating an arrangement of blocks in the imaging element according Embodiment 1;

FIG. 7 is a view illustrating an example of a layout of respective semiconductor substrates corresponding to the light detection circuit and the pixel value storage circuit which are shown in FIG. 6;

FIG. 8 is a view illustrating an example of a layout of micro bumps corresponding the light detection circuits and the pixel value storage circuits which are shown in FIG. 6;

FIG. 9 is a schematic diagram of the imaging element according to Embodiment 1 when a first chip and a second chip are stacked in the imaging element;

FIG. 10 is a circuit diagram illustrating a state where the light detection circuits and the pixel value storage circuits in the imaging element according to Embodiment 1 are arranged in respective grid-like configurations;

FIG. 11 is a timing chart focused on a global shutter operation in the imaging element according to Embodiment 1;

FIG. 12 is a circuit diagram illustrating a light detection circuit and a pixel value storage circuit in an imaging element according to Embodiment 2;

FIG. 13 a view illustrating charge transfer in an imaging element according to a comparative example;

FIG. 14 is a view illustrating charge transfer in the imaging element according to Embodiment 2;

FIG. 15 is a circuit diagram illustrating a light detection circuit and a pixel value storage circuit in an imaging element according to Embodiment 3;

FIG. 16 shows a cross-sectional view and a top view of a semiconductor chip which illustrate a structure of a pixel value storage capacitance used in the imaging element according to Embodiment 3;

FIG. 17 is a view illustrating charge transfer in the imaging element according to Embodiment 3;

FIG. 18 is a circuit diagram illustrating a light detection circuit and a pixel value storage circuit in an imaging element according to Embodiment 4;

FIG. 19 is a timing chart illustrating the operations of the light detection circuit and the pixel value storage circuit in the imaging element according to Embodiment 4;

FIG. 20 is a circuit diagram illustrating a light detection circuit and a pixel value storage circuit in an imaging element according to Embodiment 5;

FIG. 21 is a timing chart illustrating the operations of the light detection circuit and the pixel value storage circuit in the imaging element according to Embodiment 5;

FIG. 22 is a circuit diagram illustrating a light detection circuit and a pixel value storage circuit in an imaging element according to Embodiment 6;

FIG. 23 is a timing chart illustrating the operations of the light detection circuit and the pixel value storage circuit in the imaging element according to Embodiment 6;

FIG. 24 is a circuit diagram illustrating a light detection circuit and a pixel value storage circuit in an imaging element according to Embodiment 7;

FIG. 25 is a timing chart illustrating the operations of the light detection circuit and the pixel value storage circuit in the imaging element according to Embodiment 7;

FIG. 26 is a circuit diagram illustrating a light detection circuit and a pixel value storage circuit in an imaging element according to Embodiment 8;

FIG. 27 is a timing chart illustrating the operations of the light detection circuit and the pixel value storage circuit in the imaging element according to Embodiment 8;

FIG. 28 is a circuit diagram illustrating a light detection circuit and a pixel value storage circuit in an imaging element according to Embodiment 9;

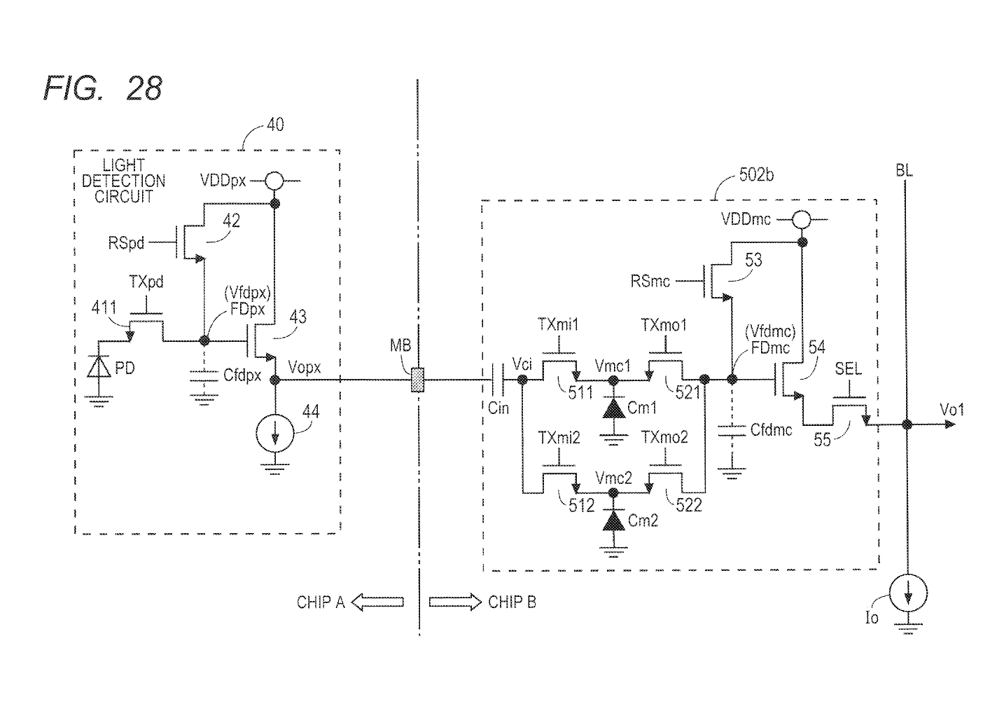

FIG. 29 is a timing chart illustrating the operations of the light detection circuit and the pixel value storage circuit in the imaging element according to Embodiment 9;

FIG. 30 is a circuit diagram illustrating a light detection circuit and a pixel value storage circuit in an imaging element according to Embodiment 10;

FIG. 31 is a timing chart illustrating the operations of the light detection circuit and the pixel value storage circuit in the imaging element according to Embodiment 10;

FIG. 32 is a circuit diagram illustrating a light detection circuit and a pixel value storage circuit in an imaging element according to Embodiment 11;

FIG. 33 is a circuit diagram illustrating a state where the light detection circuits and the pixel value storage circuits in the imaging element according to Embodiment 11 are arranged in respective grid-like configurations;

FIG. 34 is a view illustrating an example of a layout of respective semiconductor substrates corresponding to the light detection circuits and the pixel value storage circuits which are shown in FIG. 33;

FIG. 35 is a view illustrating an example of a layout of micro bumps corresponding to the light detection circuits and the pixel value storage circuits which are shown in FIG. 33; and

FIG. 36 is a schematic diagram of the imaging element according to Embodiment 11 when the first chip and the second chip are stacked in the imaging element.

### DETAILED DESCRIPTION

For the clarification of the description, the following description and the drawings may be omitted or simplified as appropriate. Throughout the drawings, the same components are denoted by the same reference symbols and overlapping descriptions will be omitted as necessary.

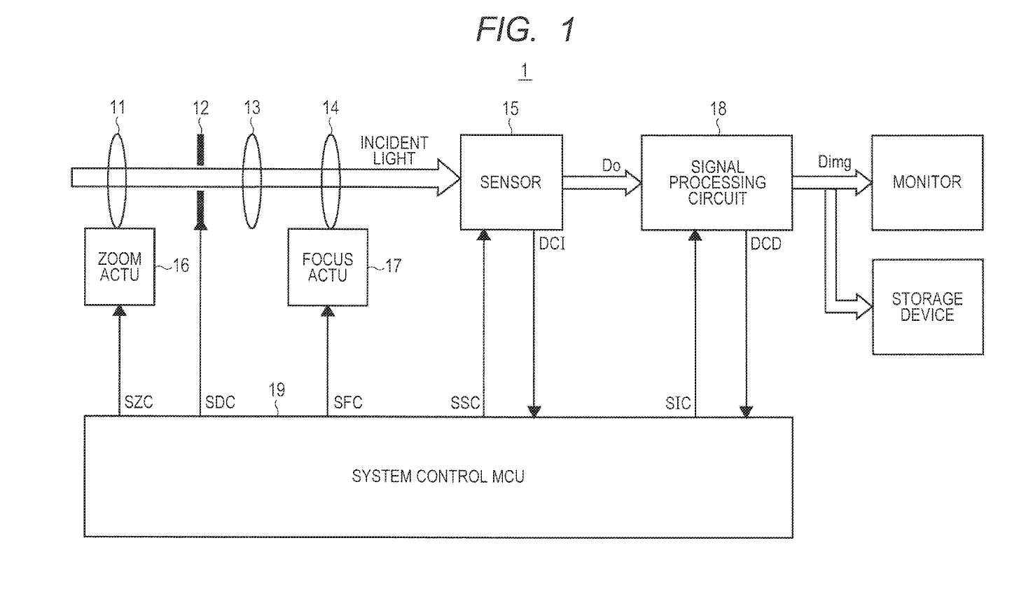

FIG. 1 shows a block diagram of a camera system 1 according to Embodiment 1. As shown in FIG. 1, the camera system 1 includes a zoom lens 11, a diaphragm mechanism 12, a fixed lens 13, a focus lens 14, an imaging element 15, a zoom lens actuator 16, a focus lens actuator 17, a signal processing circuit 18, a system control MCU 19, a monitor, and a storage device. The monitor and the storage device which are shown herein recognize an image sensed by the camera system 1 and store the sensed image. The monitor and the storage device may also be provided in another system disconnected from the camera system 1.

The zoom lens 11, the diaphragm mechanism 12, the fixed lens 13, and the focus lens 14 are included in a lens set in the camera system 1. The position of the zoom lens 11 is varied by the zoom actuator 16. The position of the focus lens 14 is varied by the focus actuator 17. In the camera system 1, by moving the lenses using the various actuators, a zoom factor and a focus are varied and, by operating the diaphragm mechanism 12, the amount of incident light is varied.

The zoom actuator 16 moves the zoom lens 11 on the basis of a zoom control signal SZC output from the system control MCU 19. The focus actuator 17 moves the focus lens 14 on the basis of a focus control signal SFC output from the system control MCU 19. The diaphragm mechanism 12 adjusts an aperture amount on the basis of an aperture control signal SDC output from the system control MCU 19.

The imaging element 15 has a photoelectric conversion element (hereinafter referred to as a light receiving element) such as, e.g., a photodiode, converts received light pixel information obtained from the light receiving element to a digital value, and outputs image information Do. The imaging element 15 also analyzes the image information Do output from the imaging element 15 and outputs image characteristic information DCI showing the characteristic feature of the image information Do. The image characteristic information DCI includes two images acquired in an auto focusing process described later. The imaging element 15 also performs pixel-by-pixel gain control on the image information Do, exposure control on the image information Do, and HDR (High Dynamic Range) control on the image information Do on the basis of a sensor control signal SSC given by the module control MCU 18. The details of the imaging element 15 will be described later.

The signal processing circuit 18 performs image processing such as image correction on the image information Do received from the imaging element 15 and outputs image data Dimg. The signal processing circuit 18 analyzes the received image information Do and outputs color space information DCD. The color space information DCD includes, e.g., brightness information and color information of the image information Do.

The system control MCU 19 controls the focus of the lens set on the basis of the image characteristic information DCI output from the imaging element 15. More specifically, the system control MCU 19 outputs the focus control signal SFC to the focus actuator 17 to control the focus of the lens set. The system control MCU 19 outputs the diaphragm control signal SDC to the diaphragm mechanism 12 to control the aperture amount of the diaphragm mechanism 12. The system control MCU 19 also generates the zoom control signal SZC in accordance with a zoom instruction given from the outside and outputs the zoom control signal SZC to the zoom actuator 16 to thus control the zoom factor of the lens set.

More specifically, as a result of the movement of the zoom lens 11 by the zoom actuator 16, the focus is shifted.

Accordingly, the system control MCU 19 calculates a positional phase difference between two object images on the basis of the two images included in the image characteristic information DCI obtained from the imaging element 15 and calculates a defocus amount for the lens set on the basis of the positional phase difference. The system control MCU 19 automatically adjusts the focus in accordance with the defocus amount. This process is autofocus control.

The system control MCU 19 calculates an exposure control value indicating the exposure setting of the imaging element 15 on the basis of the brightness information included in the color space information DCD output from the signal processing circuit 18 and controls the exposure setting and the gain setting of the imaging element 15 such that the brightness information included in the color space information DCD output from the signal processing circuit 18 approaches the exposure control value. At this time, the system control MCU 19 may also calculate a control value for the diaphragm mechanism 12 when the exposure is changed.

The system control MCU 19 also outputs a color space control signal SIC which adjusts the brightness or color of the image data Dimg on the basis of an instruction from a user. Note that the system control MCU 19 generates the color space control signal SIC on the basis of the difference between the color space information DCD acquired from the signal processing circuit 18 and the information given by the user.

The camera system 1 according to Embodiment 1 has one of characteristic features in a configuration of a path and a control method when pixel information is read out of a photodiode in the imaging element 15. Accordingly, the following will describe the imaging element 15 in greater detail.

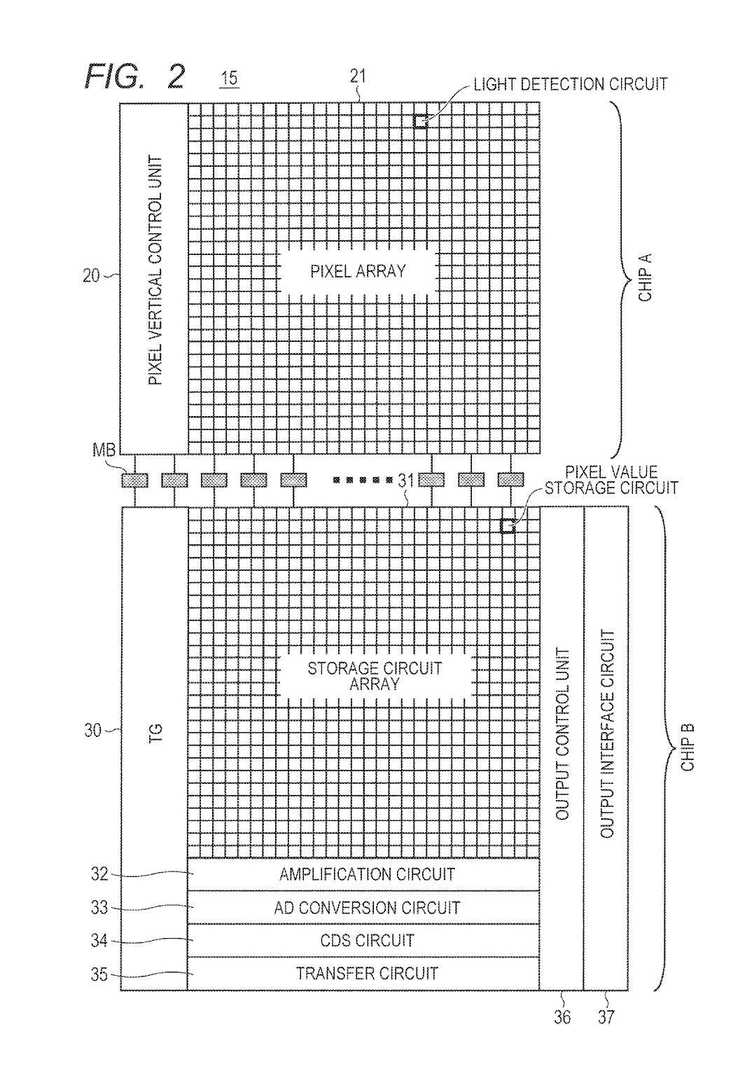

FIG. 2 shows a schematic diagram of a portion of a floor layout of the imaging element 15 according to Embodiment 1. In the example shown in FIG. 2, in the imaging element 15 according to Embodiment 1, circuits to be distributed to two chips (e.g., chips A and B) and used to generate the image information Do are disposed. FIG. 2 shows, of the floor layout of the imaging element 15, only that of a pixel vertical control unit 20, a pixel array 21, a timing generator 30, a storage circuit array 31, an amplification circuit 32, an analog/digital conversion circuit 33, a subtraction circuit (e.g., CDS (Correlated Double Sampling) circuit) 34, a transfer circuit 35, an output control unit 36, and an output interface circuit 37.

In the example shown in FIG. 2, the pixel vertical control unit 20 and the pixel array 21 are disposed in the first chip (e.g., chip A), while the timing generator 30, the storage circuit array 31, the amplification circuit 32, the analog/digital conversion circuit 33, the subtraction circuit (e.g., CDS (Correlated Double Sampling) circuit) 34, the transfer circuit 35, the output control unit 36, and the output interface circuit 37 are disposed in the second chip (e.g., chip B).

The chip A is stacked over the chip B. The pixel array 21 of the chip A is exposed so as to be exposed to light. On the other hand, the chip B is formed such that the circuits formed therein are shielded from light. For example, among the circuits formed in the chip B, at least the storage circuit array 31 is shielded from light by the chip A stacked over the chip B. The imaging element 15 according to Embodiment 1 couples the chips A and B to each other via a micro bump and performs signal transmission/reception between the first and second chips via the micro bump.

In the pixel array 21, a plurality of light detection circuits 40 are arranged in a grid-like configuration. The pixel vertical control unit 20 controls the operations of the light detection circuits 40 arranged in the pixel array 21. Note that, in the imaging element 15 according to Embodiment 1, a pixel current supply is included in each of the light detection circuits 40.

The timing generator 30 controls the timings when the storage circuit array 31, the amplification circuit 32, the analog/digital conversion circuit 33, and the CDS circuit 34 operate. In the storage circuit array 31, a plurality of pixel value storage circuits 50 are arranged in a grid-like configuration. The pixel value storage circuits 50 store voltages generated on the basis of first imaging signals output from the light detection circuits 40 and output, at predetermined timings, second imaging signals generated on the basis of the voltages stored therein.

The pixel value storage circuits 50 are provided to correspond to the light detection circuits 40. The amplification circuit 32 performs amplification of the signals read out of the pixel value storage circuits 50 and gain adjustment thereof. The analog/digital conversion circuit 33 converts the signals subjected to the gain adjustment in the amplification circuit 32 to digital values. The CDS circuit 34 outputs, as pixel values, difference values between dark level values corresponding to dark level signals which are obtained when the floating diffusions in the pixel value storage circuits 50 are reset and pixel values corresponding to the signal levels of the second imaging signals which are output from the pixel value storage circuits 50. The pixel values output from the CDS circuit 34 serve as pixel information. The CDS circuit 34 removes noise superimposed on the imaging signals therefrom. The transfer circuit 35 transfers the pixel information from which noise is removed by the CDS circuit 34 in order of increasing distance from the output control unit 36. The output interface circuit 37 is the output interface circuit of the imaging element 15.

The imaging element 15 according to Embodiment 1 has one of characteristic features in the light detection circuits 40 formed in the chip A and the pixel value storage circuits 50 formed in the chip B. Accordingly, the following will describe the light detection circuits 40 and the pixel value storage circuits 50 in the imaging element 15 in detail.

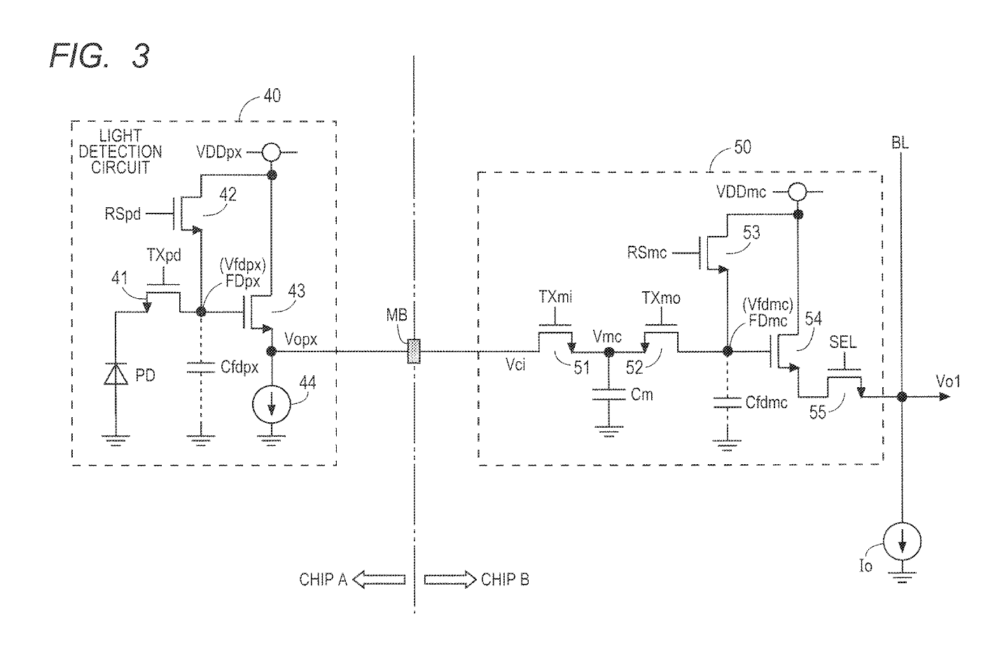

FIG. 3 shows a circuit diagram illustrating each of the light detection circuits 40 and each of the pixel value storage circuits 50 in the imaging element 15 according to Embodiment 1. As shown in FIG. 3, the light detection circuit 40 has a photodiode PD, a transfer transistor 41, a first reset transistor (e.g., a reset transistor 42), a first amplification transistor (e.g., an amplification transistor 43), a first floating diffusion (e.g., a floating diffusion FDps), and a constant current supply 44. FIG. 3 also shows a parasitic capacitance Cfdpx used as the floating diffusion FDpx.

The photodiode PD is a photoelectric conversion element having an anode to which a grounding voltage is given and a cathode which is coupled to the source of the transfer transistor 41. The transfer transistor 41 has a drain serving as the floating diffusion FDpx. The open/closed state of the transfer transistor 41 is controlled by a transfer control signal TXpd. The reset transistor 42 gives a first reset voltage to the floating diffusion FDpx in response to a first reset signal (e.g., a reset control signal RSpd). In the example shown in FIG. 3, as the first reset signal, a pixel circuit power supply voltage VDDpx is used. The amplification transistor 43 outputs the first imaging signal on the basis of the potential in the floating diffusion FDpx. The constant current supply 44 gives a load current to a source follower circuit formed of the amplification transistor 43. Note that, in the following description, the first imaging signal has a voltage Vopx, and therefore the first imaging signal is referred to as a first imaging signal voltage Vopx.

As also shown in FIG. 3, the pixel value storage circuit 50 has an input transfer transistor 51, an output transfer transistor 52, a second reset transistor (e.g., a reset transistor 53), a second amplification transistor (e.g., an amplification transistor 54), a selection transistor 55, a pixel value storage capacitance (e.g., a memory capacitance Cm), and a second floating diffusion (e.g., a floating diffusion FDmc). In the example shown in FIG. 3, the first imaging signal voltage Vopx output from the light detection circuit 40 is input to the pixel value storage circuit 50 via a micro bump MB. That is, the micro bump MB serves as an output terminal for the first imaging signal voltage Vopx in the chip A and as an input terminal for the first imaging signal voltage Vopx in the chip B.

The input transfer transistor 51 has a drain to which the first imaging signal voltage Vopx is input. In the following description, a voltage at the one of the terminals of the input transfer transistor 51 to which the first imaging signal voltage Vopx is input is referred to as a stored input voltage Vci. The open/closed state of the input transfer transistor 51 is controlled on the basis of a storage control signal TXmi.

To one end of the memory capacitance Cm, the grounding voltage is given. To the other end of the memory capacitance Cm, the source of the input transfer transistor 51 is coupled. The source of the output transfer transistor 52 is coupled to the other end of the memory capacitance Cm. The drain of the output transfer transistor 52 serves as the floating diffusion FDmc. In the example shown in FIG. 3, the parasitic capacitance used as the floating diffusion FDmc is shown as Cfdmc. The open/closed state of the output transfer transistor 52 is controlled by a read control signal TXmo.

The reset transistor 53 gives a second reset voltage to the floating diffusion FDmc in response to a second reset signal (e.g., a reset control signal RSmc). In the example shown in FIG. 3, as the second reset signal, a storage circuit power supply voltage VDDmc is used. The amplification transistor 54 outputs the second imaging signal on the basis of the potential in the floating diffusion FDmc. Note that, in the following description, the second imaging signal has a voltage Vo1, and therefore the second imaging signal is referred to as a second imaging signal voltage Vo1. The selection transistor 55 is provided between a bit line BL and the source of the amplification transistor 54. The open/closed state of the selection transistor 55 is controlled by a selection signal SEL. In the bit line BL, a load current supply Io is provided. The load current supply Io gives the load current to a source follower circuit formed of the amplification transistor 54. The load current supply Io is used commonly for the plurality of pixel value storage circuits 50 coupled to the bit line BL.

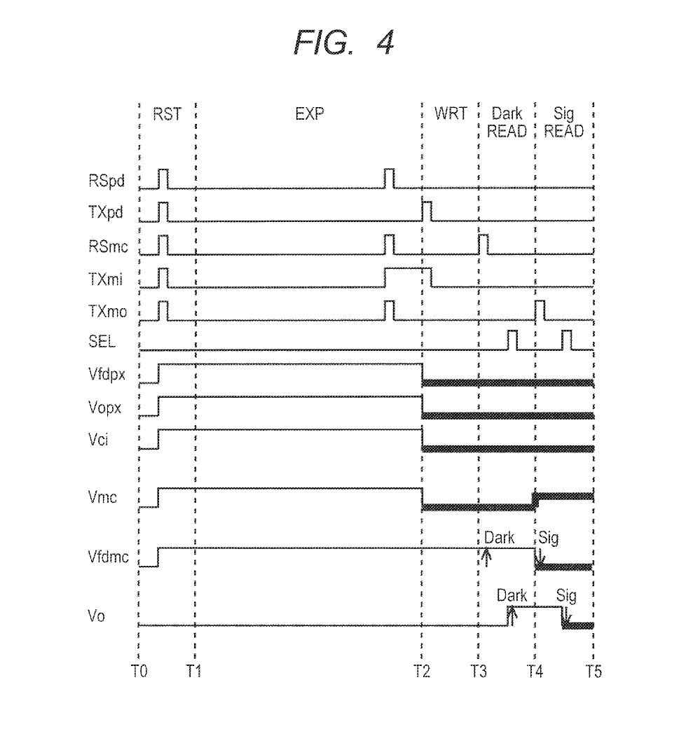

Subsequently, a description will be given of the operation of the imaging element 15 according to Embodiment 1. FIG. 4 shows a timing chart illustrating the operations of the light detection circuit 40 and the pixel value storage circuit 50 in the imaging element 15 according to Embodiment 1. Note that the control signals used in the operations described below (including those in the other embodiments) are output from the pixel vertical control unit 20 and the timing generator 30.

In the example shown in FIG. 4, during a reset period RST between the timings T0 and T1, HIGH pulses are given as the reset control signal RSpd, the reset control signal RSmc, the transfer control signal TXpd, the storage control signal TXmi, and the read control signal TXmo to give the reset voltages to the various nodes of the light detection circuit 40 and the pixel value storage circuit 50. Specifically, during the reset period RST, a voltage Vfdpx in the photodiode PD and the floating diffusion FDpx, a voltage Vfdmc in the floating diffusion FDmc, a stored voltage Vmc as the voltage in the memory capacitance Cm, and the stored input voltage Vci in the parasitic capacitance of the micro bump MB are each to the reset voltages.

The period between the timings T1 and T2 is an exposure period EXP. During the exposure period EXP, the transfer control signal TXpd is held at a LOW level. During the exposure period EXP, HIGH pulses are given as the reset control signal RSpd, the reset control signal RSmc, the storage control signal TXmi, and the read control signal TXmo to reset the voltage Vfdpx in the floating diffusion FDpx, the voltage Vfdmc in the floating diffusion FDmc, and the stored input voltage Vci to the reset voltages.

The period between the timings T2 and T3 is a memory write period WRT. During the memory write period WRT, each of the reset control signal RSpd, the reset control signal RSmc, and the read control signal TXmo is brought to the LOW level, while each of the transfer control signal TXpd and the storage control signal TXmi is brought to a HIGH level. As a result, the charges generated in the photodiode PD exposed to light are transferred to the floating diffusion FDpx and, in response thereto, the amplification transistor 43 outputs the first imaging signal voltage Vopx. The first imaging signal voltage Vopx output from the amplification transistor 43 is input to the pixel value storage circuit 50. In the pixel value storage circuit 50, charges resulting from the first imaging signal voltage Vopx input thereto are stored in the memory capacitance Cm.

The period between the timings T3 and T4 is a dark level read period DarkREAD. During the dark level read period DarkREAD, the reset control signal RSmc is brought to the HIGH level to give the reset voltage to the floating diffusion FDmc. In addition, the amplification transistor 54 outputs the dark level signal on the basis of the reset voltage. The dark level signal is read out to the bit line BL upon shifting of the selection signal SEL the HIGH level.

The period between the timings T4 and T5 is an imaging signal read period SigREAD. During the imaging signal read period SigREAD, the read control signal TXmo is brought to the HIGH level to transfer the charges stored in the memory capacitance Cm to the floating diffusion FDmc. In addition, the amplification transistor 54 outputs the second imaging signal voltage Vo1 on the basis of the voltage in the floating diffusion FDmc. The second imaging signal voltage Vo1 is read out to the bit line BL upon shifting of the selection signal SEL to the HIGH level.

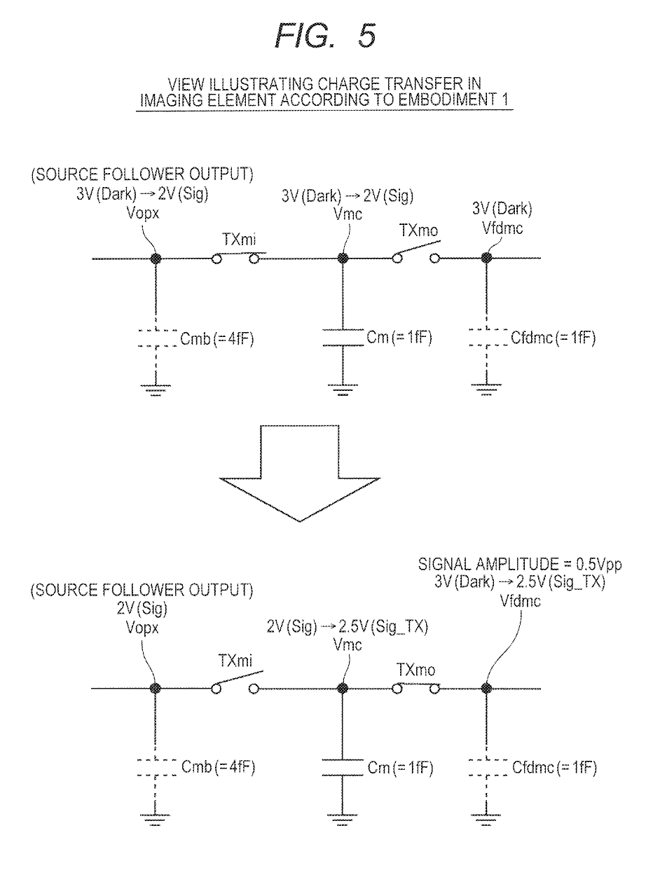

Referring to FIG. 5, a description will be given of the quantity of charges transferred to the floating diffusion FDmc. In the example shown in FIG. 5, a parasitic capacitance Cmb of the micro bump is shown. In FIG. 5, as the reset voltage which provides a dark level, 3 V (shown as 3 V (Dark) in FIG. 5) is used. In the example shown in FIG. 5, it is assumed that the parasitic capacitance Cmb in the micro bump is 4 fF, the memory capacitance Cm is 1 fF, and the parasitic capacitance Cfdmc serving as the floating diffusion FDmc is 1 fF.

As shown in FIG. 5, in the imaging element 15 according to Embodiment 1, the light detection circuit 40 outputs the first imaging signal voltage Vopx from the source follower circuit. Accordingly, when the first imaging signal voltage Vopx drops from 3 V to 2 V as a result of exposure, the source follower circuit of the light detection circuit 40 drives each of the parasitic capacitance Crab and the memory capacitance Cm such that a voltage resulting from the parasitic capacitance Cmb and the memory capacitance Cm is 2 V (shown as 2 V (Sig) in FIG. 5). As a result, the voltage Vrnc in the memory capacitance Cm changes from 3 V to 2 V.

In the example shown in FIG. 5, when charges are transferred from the memory capacitance Cm to the floating diffusion FDmc, the voltage Vfdmc in the floating diffusion FDmc changes from 3 V to 2.5 V (shown as 2.5 V (Sig_TX) in FIG. 5). This is because, by turning ON the output transfer transistor 52, the memory capacitance Cm and the parasitic capacitance Cfdmc serving as the floating diffusion FDmc are combined with each other. Due to the combined capacitance, the charges stored in the two capacitances are re-distributed such that the stored voltage Vmc in the memory capacitance Cm is equal to the voltage Vfdmc in the floating diffusion FDmc.

Thus, in the imaging element 15 according to Embodiment 1, the light detection circuit 40 outputs the first imaging signal voltage Vopx from the source follower circuit, and the memory capacitance Cm stores the first imaging signal voltage Vopx via the input transfer transistor 51. As a result, the amplitude of the voltage to be amplified by the amplification transistor 54 is 0.5 Vpp.

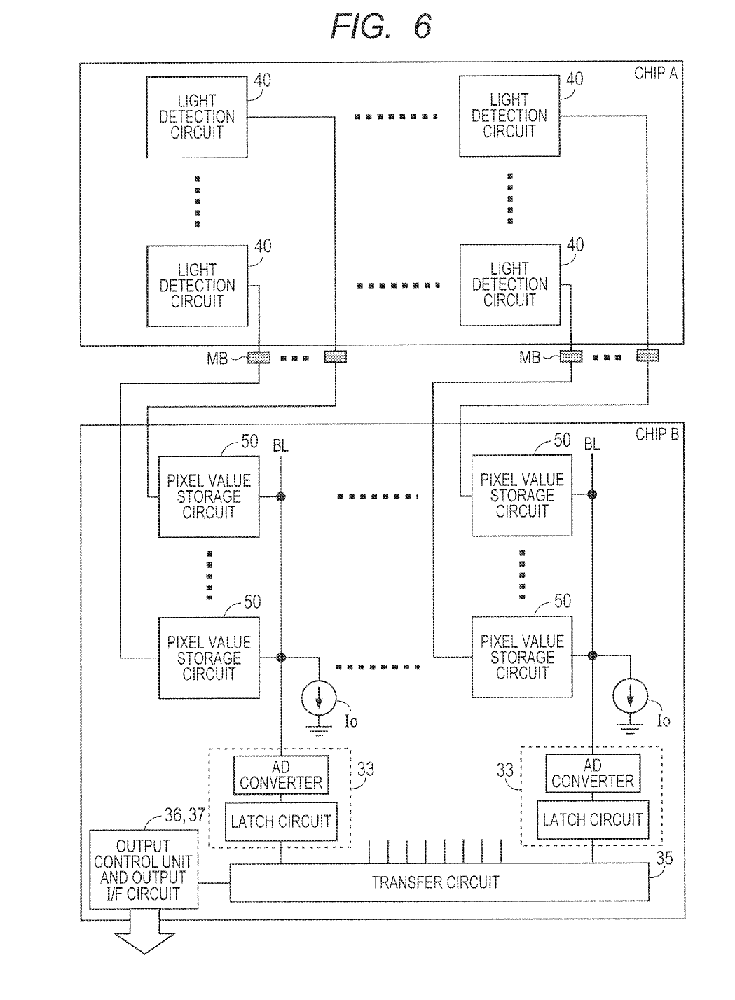

A more specific description will be given of a block configuration of the imaging element 15 according to Embodiment 1. FIG. 6 shows a view illustrating an arrangement of blocks in the imaging element according to Embodiment 1. As shown in FIG. 6, in the chip A, the plurality of light detection circuits 40 are arranged in a grid-like configuration. The plurality of light detection circuits 40 transmit the first imaging signals to the chip B via the respective micro bumps MB. The pixel value storage circuits 50 are provided to correspond to the light detection circuits 40 and arranged in the grid-like configuration in the chip B. Each of the pixel value storage circuits 50 receives the first imaging signal from the corresponding light detection circuit 40 via the micro bump MB.

The chip B has the bit lines BL each provided therein to correspond to those of the plurality of pixel value storage circuits 50 arranged in the grid-like configuration which are disposed in the same column. For each one of the bit lines BL, the load current supply Io is provided. At one end of the bit line BL, the analog/digital conversion circuit 33 is provided. The analog/digital conversion circuit 33 includes an AD (Analog-to-Digital) converter and a latch circuit. Output values from the plurality of analog/digital conversion circuits 33 are output via the transfer circuit 35, the output control unit 36, and the output interface circuit 37.

Note that the view shown in FIG. 6 is intended to mainly illustrate the coupling/positional relationships between the light detection circuits 40 and the pixel value storage circuits 50. The illustration of the pixel vertical control unit 20, the timing generator 30, the amplification circuit 32, and the CDS circuit 34 is omitted.

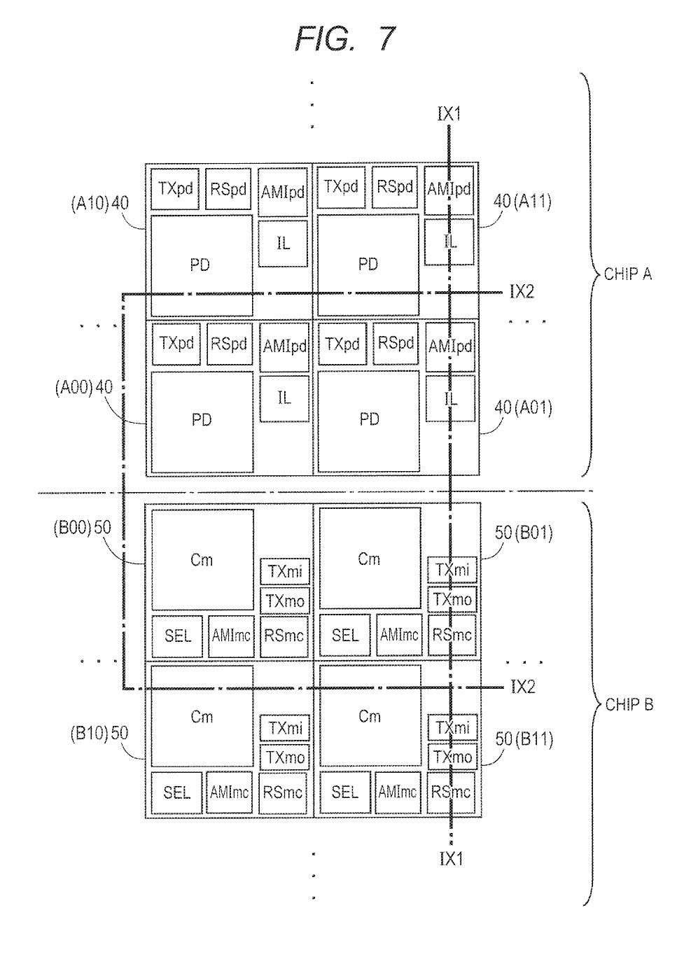

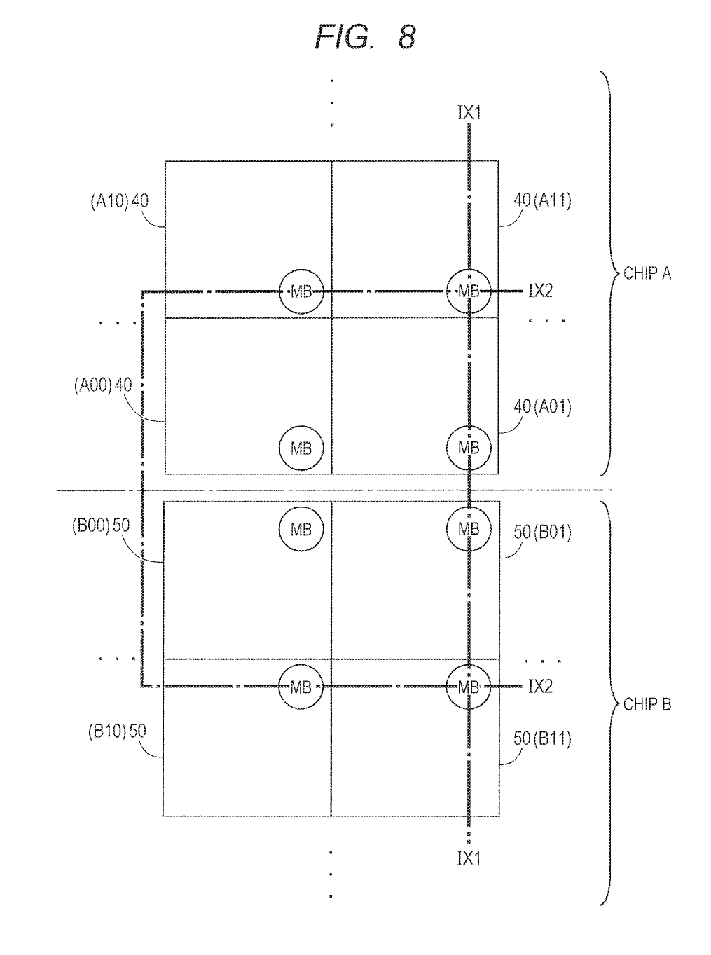

Subsequently, a description will be given of a layout of the light detection circuits 40 and the pixel value storage circuits 50. FIG. 7 shows a view illustrating an example of a layout of respective semiconductor substrates corresponding to the light detection circuit 40 and the pixel value storage circuit 50 which are shown in FIG. 3. Note that, in FIG. 7, two pairs of the light detection circuits 40 and the pixel value storage circuits 50 are shown in a row direction, while two pairs of the light detection circuits 40 and the pixel value storage circuits 50 are shown in a column direction. However, in a real imaging element, an enormous number of the light detection circuits 40 and an enormous number of the pixel value storage circuits 50 are disposed. In FIG. 7 and FIG. 8 described later, to clearly show the positions of the individual circuits over the chips, A00, A01, A10, A11, B00, B01, B10, and B11 showing the positions where the circuits are disposed are shown.

As shown in FIG. 7, over the semiconductor substrate of the chip A, the plurality of light detection circuits 40 are arranged in the grid-like configuration. On the other hand, over the semiconductor substrate of the chip B, the plurality of pixel value storage circuits are arranged in the grid-like configuration. In each of the light detection circuits 40, the photodiode PD, the transfer transistor 41 (TXpd in FIG. 7), the reset transistor 42 (RSpd in FIG. 7), the amplification transistor (AMIpd in FIG. 7), and the constant current supply 44 (IL in FIG. 7) are formed.

In each of the pixel value storage circuits 50, the memory capacitance Cm, the input transfer transistor 51 (TXmi in FIG. 7), the output transfer transistor 52 (TXmo in FIG. 7), the reset transistor 53 (RSmc in FIG. 7), the amplification transistor 54 (AMImc in FIG. 7), and the selection transistor 55 (SEL in FIG. 7) are formed.

In the imaging element 15 according to Embodiment 1, the micro bumps MB of the chip A and the micro bumps MB of the chip B are formed of wiring layers formed over the semiconductor substrates. FIG. 8 is a view illustrating an example of a layout of the micro bumps corresponding to the light detection circuit and the pixel value storage circuit which are shown in FIG. 3. The layout shown in FIG. 6 is obtained by extracting those of the wiring layers of the chips A and B in which the micro bumps MB are formed. As shown in FIG. 8, in the chips A and B in the imaging element 15 according to Embodiment 1, the micro bumps MB are formed in the uppermost wiring layers provided away from the semiconductor substrates.

The micro bumps MB of the light detection circuits 40 and the micro bumps MB of the pixel value storage circuits 50 are disposed at respective positions which are line-symmetrical with each other relative to the dot-dash line in FIG. 7 used as an axis of symmetry. By disposing the micro bumps at such positions and bonding the chips A and B together using the dot-dash line as the axis of symmetry, the micro bumps BM of the two chips are coupled to each other.

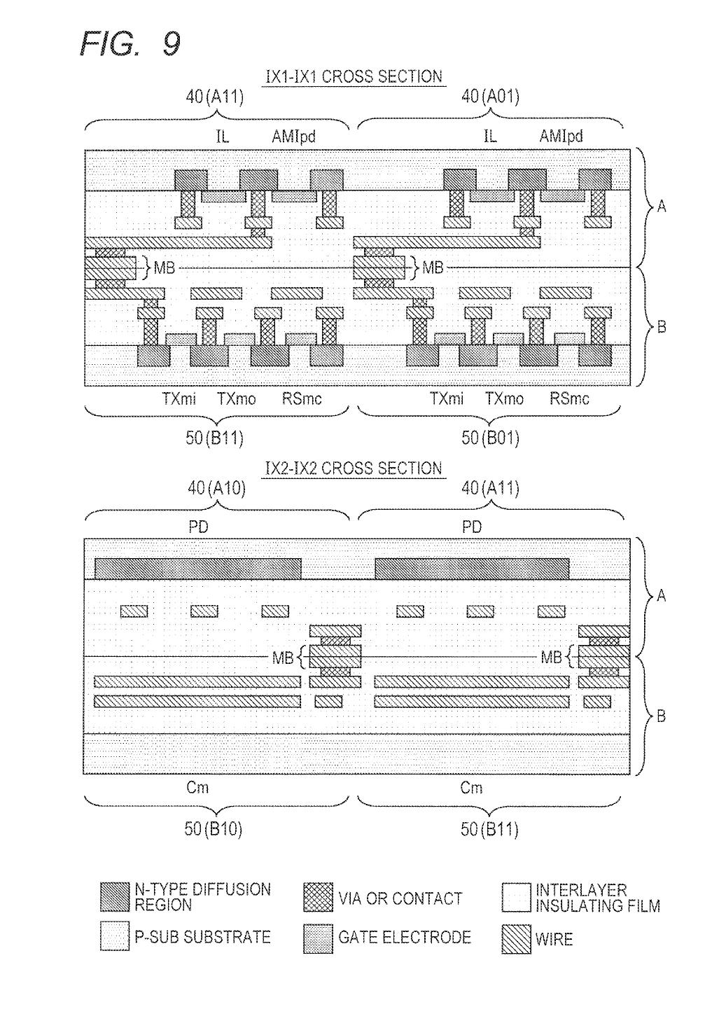

FIG. 9 shows a schematic diagram of the imaging element when the first and second chips in the imaging element according to Embodiment 1 are stacked. In FIG. 9, a cross-sectional view of the imaging element 15 along the line IX1-IX1 in FIGS. 7 and 6 is shown as an upper drawing, while a cross-sectional view of the imaging element 15 along the line IX2-IX2 in FIGS. 7 and 6 is shown as a lower drawing. It is assumed that, in the imaging element 15 according to Embodiment 1, the back-side-illumination light detection circuits 40 which output the imaging signals in accordance with light incident on the semiconductor substrate side (surface facing the surface where circuits are formed) are used in the chip A. As shown in FIG. 9, in the imaging element 15 according to Embodiment 1, the chip A is stacked in flipped relation over the chip B. As also shown in FIG. 9, the two chips are bonded together such that the pixel value storage circuits 50 and the light detection circuits 40 which are disposed at the corresponding positions over the chips are stacked at the same positions. For instance, in the example shown in FIG. 9, over the pixel value storage circuit 50 disposed at the position B11, the light detection circuit 40 disposed at the position A11 is stacked.

The electrodes (e.g., electrodes serving as the micro bumps MB) formed over the chips A and B face each other as a result of stacking the chip A in flipped relation over the chip B. The electrodes formed at places facing each other at the same positions form the micro bumps MB as a result of bonding the two chips together so that the imaging element 15 according to Embodiment 1 is assembled. Note that, when the chips A and B are bonded together, the two chips are in nearly direct contact with each other. The elements included in the circuits formed in the chip B, such as transistors, are shielded from light by the metal wires of the chip B. In the imaging element 15 according to Embodiment 1, the memory capacitance Cm is formed by forming, as the electrodes of the memory capacitance Cm, two wires at vertically overlapping positions in different layers and using an interlayer insulating film formed in the region interposed between the two wires as the dielectric material of the memory capacitance Cm.

In the layout example shown in FIGS. 7 to 9, a circuit element such as a transistor is not disposed in a layer below the micro bumps MB. By thus not disposing a circuit in the layer below the micro bumps MB, it is possible to reduce the parasitic capacitance of each of the micro bumps MB. By thus reducing the parasitic capacitance related to the micro bump MB, the capacitance to be driven by the source follower circuit of the light detection circuit 40 is reduced. Accordingly, it is possible to increase the rising speed of the imaging signal output from the source follower and improve the operating speed of the imaging element 15.

In the imaging element 15 according to Embodiment 1 shown in FIG. 9, with the chips A and B being bonded together, the photodiodes PD of the plurality of light detection circuits 40 formed over the top surface of the chip A (the photodiodes PD of the light detection circuits 40 formed at the positions A00, A01, A10, and A11 in FIG. 7 or the photodiodes PD of the light detection circuits 40 formed at the positions A10 and A11 in FIG. 9) are simultaneously exposed to light. The charges generated in the plurality of photodiodes PD by the exposure are simultaneously transferred to the floating diffusions FDpx (not shown in FIGS. 7 to 9) subjected to the resetting process performed by the reset transistors 42 (denoted by RSpd in the light detection circuits 40 formed at the positions A00, A01, A10, and A11 in FIG. 7 and not shown in FIG. 9) via the transfer transistors 41 (denoted by TXpd in the light detection circuits 40 formed at the positions A00, A01, A10, and A11 in FIG. 7 and not shown in FIG. 9). Then, the amplification transistors 43 (denoted by AMIpd in the light detection circuits 40 formed at the positions A00, A01, A10, and A11 in FIG. 7 or AMIpd in the light detection circuits 40 formed at the positions A10 and A11 in FIG. 9) provided in the individual light detection circuits 40 generate the first imaging signals on the basis of voltages resulting from the charges transferred to the floating diffusions FDpx provided to correspond to the respective amplification transistors 43 and simultaneously transfer the first imaging signals to the memory capacitances Cm (denoted by Cm in the pixel value storage circuits 50 formed at the positions B00, B01, B10, and B11 in FIG. 7 or Cm in the pixel value storage circuits 50 formed at the positions B10 and B11 in FIG. 9) of the corresponding pixel value storage circuits 50. At this time, the input transfer transistors 53 (denoted by TXmi in the pixel value storage circuits 50 formed at the positions B00, B01, B10, and B11 in FIG. 7 or TXmi in the pixel value storage circuits 50 formed at the positions B10 and B11 in FIG. 9) of the pixel value storage circuits 50 are in an ON state. In the chip B, by bringing the input transfer transistors 53 of the plurality of pixel value storage circuits 50 into an OFF state, the values of the transferred first imaging signals are stored.

Note that the constant current supplies 44 which give the load currents to the amplification transistors 43 are denoted by IL in the light detection circuits 40 formed the position A00, A01, A10, and A11 in FIG. 7 or IL in the light detection circuits 40 formed at the positions A10 and A11 in FIG. 9. The first imaging signals are transmitted from the chip A to the chip B via the micro bumps MB (denoted by MB in the pixel value storage circuits 50 formed at the positions A00, A01, A10, and A11 and MB in the pixel value storage circuits 50 formed at the positions B00, B01, B10, and B11 in FIG. 8 or MB formed between the bonded surfaces of the chips A and B in FIG. 9 to couple the two chips to each other).

The chip B has the bit lines each provided commonly for the plurality of pixel value storage circuits 50 (circuits formed at the positions B00, B01, B10, and B11 in FIGS. 7 to 9) disposed in the same column (in FIGS. 7 and 8, the positions B00 and B10 are in the same column and the positions B01 and B11 are in the same column). The plurality of pixel value storage circuits 50 bring the output transfer transistors 52 (denoted by TXmo in the pixel value storage circuits 50 formed at the positions B00, B01, B10, and B11 in FIG. 7 or TXmo in the pixel value storage circuits 50 formed at the positions B10 and B11 in FIG. 9) into the ON state at timings different from one row to another. Thus, the plurality of pixel value storage circuits 50 transfer charges to the floating diffusions FDmc (not shown in FIGS. 7 to 9) subjected to the resetting process performed by the reset transistors (denoted by RSmc in the pixel value storage circuits 50 formed at the positions B00, B01, B10, and B11 in FIG. 7 or RSmc in the pixel value storage circuits 50 formed at the positions B10 and B11 in FIG. 9) at timings different from one row to another. Then, the plurality of light detection circuits 40 generate the second imaging signals having voltage values based on the voltages generated in the floating diffusions FDmc by the amplification transistors 54 (denoted by AMI in the pixel value storage circuits 50 formed at the positions B00, B01, B10, and B11 in FIG. 7 and not shown in FIG. 9) at timings different from one row to another. In the chip B, the selection transistors 55 (denoted by SEL in the pixel value storage circuits 50 formed at the positions B00, B01, B10, and B11 in FIG. 7 and not shown in FIG. 9) are brought into the ON state at timings different from one row to another. Thus, in the chip B, the second imaging signals are output to the corresponding bit lines at timings different from one row to another.

That is, the imaging element 15 according to Embodiment 1 performs an imaging operation in a global shutter mode. The following description will be given by focusing attention on the operations of one of the light detection circuits and one of the pixel value storage circuits 50 but, in an actual situation, the imaging signals are simultaneously transferred from the plurality of light detection circuits 40 to the plurality of pixel value storage circuits 50. Also, in the imaging element 15 according to Embodiment 1, pixel signals are output from the pixel value storage circuits 50 on a per-row basis.

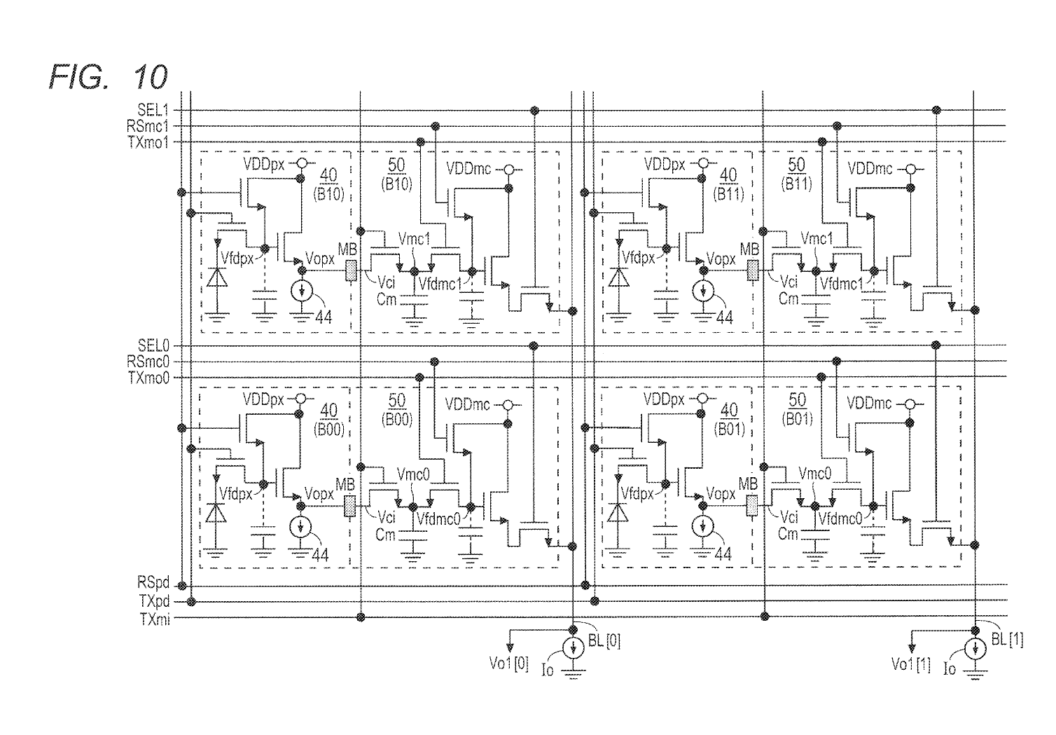

The following will describe the operation in the global shutter mode in the imaging element 15 according to Embodiment 1. FIG. 10 shows a circuit diagram illustrating the state where the light detection circuits 40 and the pixel value storage circuits in the imaging element 15 according to Embodiment 1 are arranged in the respective grid-like configurations. As shown in FIG. 10, the imaging element 15 according to Embodiment 1 is coupled to the bit lines BL extending in the column direction in accordance with such coupling relations between the circuits as shown below. That is, the light detection circuit 40 disposed at the position A00 is coupled to a bit line BL[0] via the pixel value storage circuit 50 disposed at the position B00, while the light detection circuit 40 disposed at the position A10 is coupled to the bit line BL[0] via the pixel value storage circuit 50 disposed at the position B10. The light detection circuit 40 disposed at the position A01 is coupled to a bit line BL[1] via the pixel value storage circuit 50 disposed at the position B01, while the light detection circuit 40 disposed at the position A11 is coupled to the bit line BL[0] via the pixel value storage circuit 50 disposed at the position B11.

In each of the bit lines BL[0] and BL[1], the load current supply Io is provided. Also, as shown in FIG. 10, in each of the light detection circuits 40, the constant current supply 44 is provided. That is, in each of the light detection circuits 40 disposed in the chip A, the constant current supply 44 is provided on a per-circuit basis. In the chip B, for each one of the bit lines BL to which the plurality of pixel storage circuits 50 disposed in the same column are coupled, the one load current supply Io is provided.

As also shown in FIG. 10, the light detection circuits 40 are controlled by control signals (e.g., the transfer control signals TXpd and the reset control signals RSpd) having logic levels which simultaneously shift with respect to the plurality of circuits. On the other hand, in the pixel value storage circuits 50, the storage control signals TXmi are given such that the logic levels thereof shift at the same timing irrespective of the positions at which the circuits are disposed, while the read control signals TXmo, the reset control signals Rsmc, and the selection signals SEL are given such that the logic levels thereof shift at timings which differ depending on the rows in which the circuits are disposed on a row-by-row basis. In FIG. 10, the read control signals TXmo, the reset control signals RSmc, and the selection signals SEL have numbers showing the row numbers at the ends of the reference marks thereof.

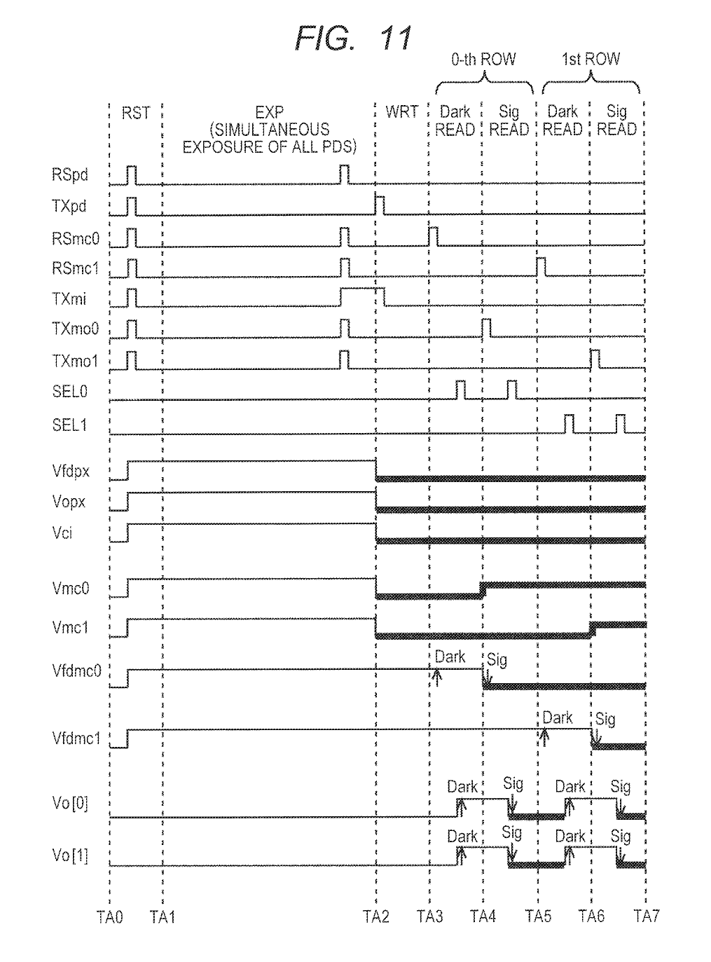

Subsequently, a description will be given of a global shutter operation in the imaging element 15 according to Embodiment 1. FIG. 11 shows a timing chart focusing on the global shutter operation in the imaging element 15 according to Embodiment 1.

In the example shown in FIG. 11, during the reset period RST between the timings TA0 and TA1, HIGH pulses are given as the reset control signals RSpd, the reset control signals RSmc, the transfer control signals TXpd, the storage control signals TXmi, and the read control signals TXmo to give the reset voltages to the various nodes of the light detection circuits 40 and the pixel value storage circuits 50. Specifically, during the reset period RST, the voltages Vfdpx in the photo diodes PD and the floating diffusions FDpx, the voltages Vfdmc in the floating diffusions FDmc, the stored voltages Vmc as the voltages in the memory capacitances Cm, and the stored input voltages Vci in the parasitic capacitances of the micro bumps MB are reset to the reset voltages. During the reset period RST, operations are simultaneously performed on all the light detection circuits 40 and the pixel value storage circuits 50.

The period between the timings TA1 and TA2 is the exposure period EXP. During the exposure period EXP also, operations are simultaneously performed on all the light detection circuits 40 and the pixel value storage circuits 50. During the exposure period EXP, the transfer control signals TXpd are held at the LOW level. During the exposure period EXP, HIGH pulses are given as the reset control signals RSpd, the reset control signals RSmc, the storage control signals TXmi, and the read control signals TXmo to reset the voltages Vfdpx in the floating diffusions FDpx, the voltages Vfdmc in the floating diffusions FDmc, and the stored input voltages Vci to the reset voltages.

The period between the timings TA2 and TA3 is the memory write period WRT. During the memory write period WRT also, operations are simultaneously performed on all the light detection circuits 40 and the pixel value storage circuits 50. During the memory write period WRT, the reset control signals RSpd, the reset control signals RSmc, and the read control signals TXmo are brought to the LOW level, while the transfer control signals TXpd and the storage control signals TXmi are brought to the HIGH level. As a result, the charges generated in the exposed photodiodes PD are transferred to the floating diffusions FDpx and, in response thereto, the amplification transistors 43 output the first imaging signal voltages Vopx. The first imaging signal voltages Vopx output from the amplification transistors 43 are input to the pixel value storage circuits 50. In the pixel value storage circuits 50, charges resulting from the first imaging signal voltages Vopx input thereto are stored in the memory capacitances Cm.

During the period between the timings TA3 and TA5, the imaging signals are read first from the pixel value storages circuits 50 disposed in the 0-th row. Specifically, the period between the timings TA3 and TA4 is the dark level read period DarkREAD during which dark level signals are read out of the pixel value storage circuits 50 disposed in the 0-th row. During the dark level read period DarkREAD, a reset control signal RSmc0 is brought to the HIGH level to give the reset voltage to the floating diffusions FDmc of the pixel value storage circuits 50 disposed at the positions B00 and B01. Then, on the basis of the reset voltage, the amplification transistors 54 of the pixel value storage circuits 50 disposed at the positions B00 and B01 output the dark level signals. The dark level signals are read out to the bit lines BL[0] and BL[1] upon shifting of the selection signal SEL0 to the HIGH level.

The period between the timings TA4 and TA5 is the imaging signal read period SigREAD during which the imaging signals are read out of the pixel value storage circuits 50 disposed in the 0-th row. During the imaging signal read period SigREAD, a read control signal TXmo0 is brought to the HIGH level to transfer the charges stored in the memory capacitances Cm of the pixel value storage circuits 50 disposed at the positions B00 and B01 to the floating diffusions FDmc. In the pixel value storage circuit 50 disposed at the position B00, the amplification transistor 54 outputs a second imaging signal voltage Vo1[0] on the basis of the voltage in the floating diffusion FDmc. Upon shifting of a selection signal SEL0 to the HIGH level, a second imaging signal Vo[0] is read out to the bit line BL[0]. In the pixel value storage circuit 50 disposed at the position B01, the amplification transistor 54 outputs a second imaging signal voltage Vo1[1] on the basis of the voltage in the floating diffusion FDmc. Upon shifting of the selection signal SEL0 to the HIGH level, the second imaging signal Vo[1] is read out to the bit line BL[1].

During the period between the timings TA5 and TA7, the imaging signals are read out of the pixel value storage circuits 50 disposed in the 1st row. Specifically, the period between the timings TA5 and TA6 is the dark level read period DarkREAD during which the dark level signals are read out of the pixel value storage circuits 50 disposed in the 1st row. During the dark level read period DarkREAD, a reset control signal RSmc1 is brought to the HIGH level to give the reset voltage to the floating diffusions FDm of the pixel value storage circuits 50 disposed at the positions B10 and B11. Then, the amplification transistors 54 of the pixel value storage circuits 50 disposed at the positions B10 and B11 output the dark level signals on the basis of the reset voltage. Upon shifting of a selection signal SEL1 to the HIGH level, the dark level signals are read out to the bit lines BL[0] and BL[1].

The period between the timings TA6 and TA7 is the imaging signal read period SigREAD during which the imaging signals are read out of the pixel value storage circuits 50 disposed in the 1st row. During the imaging signal read period SigREAD, a read control signal TXmo1 is brought to the HIGH level to transfer the charges stored in the memory capacitances Cm of the pixel value storage circuits 50 disposed at the positions B10 and B11 to the floating diffusions FDmc. In the pixel value storage circuit 50 disposed at the position B10, the amplification transistor 54 outputs the second imaging signal voltage Vo1[0] on the basis of the voltage in the floating diffusion FDmc. Upon shifting of the selection signal SEL1 to the HIGH level, the second imaging signal Vo[0] is read out to the bit line BL[0]. In the pixel value storage circuit 50 disposed at the position B11, the amplification transistor 54 outputs the second imaging signal voltage Vo1[1] on the basis of the voltage in the floating diffusion FDmc. Upon shifting of the selection signal SEL1 to the HIGH level, the second imaging signal Vo[1] is read out to the bit line BL[1].

As described above, in the imaging element 15 according to Embodiment 1, the light detection circuits 40 transfer the voltages generated on the basis of charges resulting from the exposure of the photodiodes PD to light as the first imaging signal voltages Vopx to the pixel value storage circuits 50 shielded from light via the source follower circuits. At this time, in the imaging element 15 according to Embodiment 1, voltages resulting from the first imaging signal voltages Vopx are stored in the memory capacitances Cm via the input transfer transistors 51. As a result, in the imaging element 15 according to Embodiment 1, the voltages stored in the memory capacitances Cm are not affected by the charges resulting from the exposure. Therefore, it is possible to prevent noise from contaminating the voltages stored in the memory capacitances Cm. That is, in the imaging element 15 according to Embodiment 1, by outputting the second imaging signal voltages Vo1 on the basis of the voltages stored in the memory capacitances Cm, the S/N (Signal/Noise) ratios of the imaging signals can be increased.

Also, in the imaging element 15 according to Embodiment 1, the first imaging signal voltages Vops to be given to the chip B are generated from the source follower circuits. As a result, the imaging element 15 according to Embodiment 1 is free from an operation in which the charges stored in the floating diffusions FDpx are transferred by being distributed between the capacitance values of the floating diffusions FDpx and the capacitance values of the memory capacitances Cm. In the imaging element 15 according to Embodiment 1, the charges stored in the floating diffusions FDpx are transferred to the memory capacitances Cm by the first imaging signal voltages Vopx generated on the basis of the charges stored in the floating diffusions FDpx. In short, in the imaging element 15 according to Embodiment 1, it is possible to increase the signal levels of the imaging signals transferred to the memory capacitances Cm. Consequently, in the imaging element 15 according to Embodiment 1, the S/N ratios of the imaging signals can further be increased.

In the global shutter mode, the imaging signals generated in the light detection circuits 40 are simultaneously transferred to the pixel value storage circuits 50. However, the timings when the pixel value storage circuits 50 output the imaging signals on the basis of the transferred pixel signals are different on a row-by-row basis. That is, in the global shutter mode, the time periods from when the imaging signals are stored to when the imaging signals are read are different depending on the rows in which the pixel storage circuits 50 are disposed on a row-by-row basis. Accordingly, in the global shutter mode, the stability of the stored voltages Vmc during the period during which the charges are stored in the pixel value storage circuits 50 is significantly important. In the imaging element 15 according to Embodiment 1, the input transfer transistors 51 prevent the charges generated by the light incident on the chip A from flowing into the memory capacitances Cm during the period during which the charges are stored in the pixel value storage circuits 50. As a result, in the imaging element 15 according to Embodiment 1, the stored voltages Vmc can stably be stored during the period during which the charges are stored in the pixel value storage circuits 50. Therefore, it is possible to more remarkably improve the S/N ratios in the global shutter mode.

### Embodiment 2

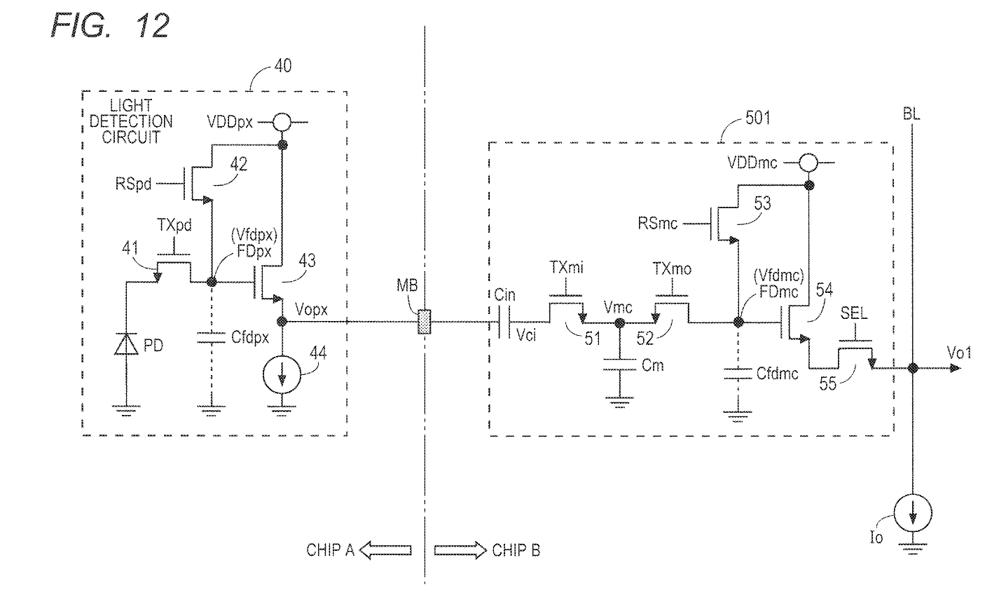

In Embodiment 2, a description will be given of a pixel value storage circuit 501 as another form of the pixel value storage circuit 50 according to Embodiment 1. FIG. 12 shows a circuit diagram illustrating the light detection circuit 40 and the pixel value storage circuit 501 in the imaging element 15 according Embodiment 2. Note that, in the description of Embodiment 2, the same components as those described in Embodiment 1 are denoted by the same reference numerals as used in Embodiment 1 and a description thereof is omitted.

As shown in FIG. 12, the pixel value storage circuit 501 according to Embodiment is obtained by adding a coupling capacitance Cin to the pixel value storage circuit 50. The coupling capacitance Cin is inserted in the wire coupling the terminal where the micro bump is provided to the input transfer transistor 51.

In the imaging element 15 according to Embodiment 2, by storing the first imaging signal voltage Vopx output from the source follower circuit of the light detection circuit 40 in the memory capacitance Cm via the coupling capacitance Cin, it is possible to prevent a drop in the voltage stored in the memory capacitance Cm.

Accordingly, a description will be given of charge transfer in the pixel value storage circuit 501 according to Embodiment 2. By contrasting an imaging element according to a comparative example with the imaging element according to Embodiment 2, the description will be given herein of the effect of improving the S/N ratio in the pixel value storage circuit 501 according to Embodiment 2.

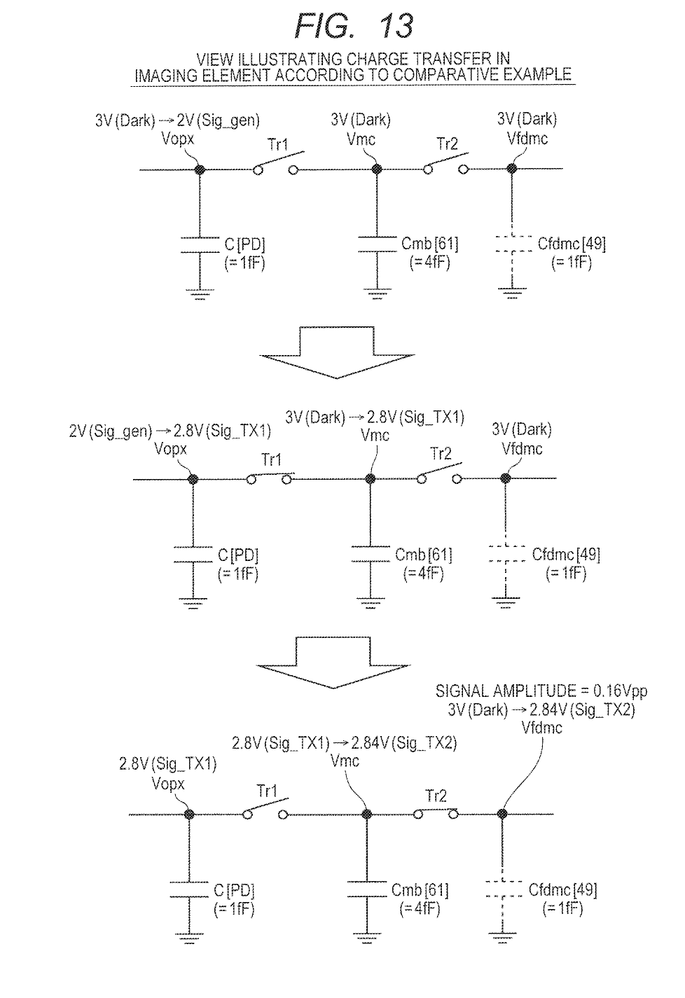

The imaging element according to the comparative example has a configuration designed by the present inventors on the basis of the statement in Patent Document 1. In FIG. 13, the marks in the brackets [ ] correspond to the marks in Patent Document 1. FIG. shows a view illustrating charge transfer in the imaging element according to the comparative example.

As shown in FIG. 13, in the imaging element according to the comparative example, the charges in the photodiode PD (C[PD] in FIG. 13) are transferred to a storage capacitance (Cmb[61] in FIG. 13) via a first transfer transistor Tr1. Also, in the configuration according to the comparative example, the charges stored in the storage capacitance are transferred to a floating diffusion (Cfdmc[49] in FIG. 13) via a second transfer transistor Tr2. In the example shown in FIG. 13, it is assumed that the voltage of a dark level signal is 3 V. Also, in the example shown in FIG. 13, it is assumed that the capacitance value of the photodiode PD is 1 fF, the capacitance value of the storage capacitance is 4 fF, and the capacitance value of the floating diffusion is 1 fF.

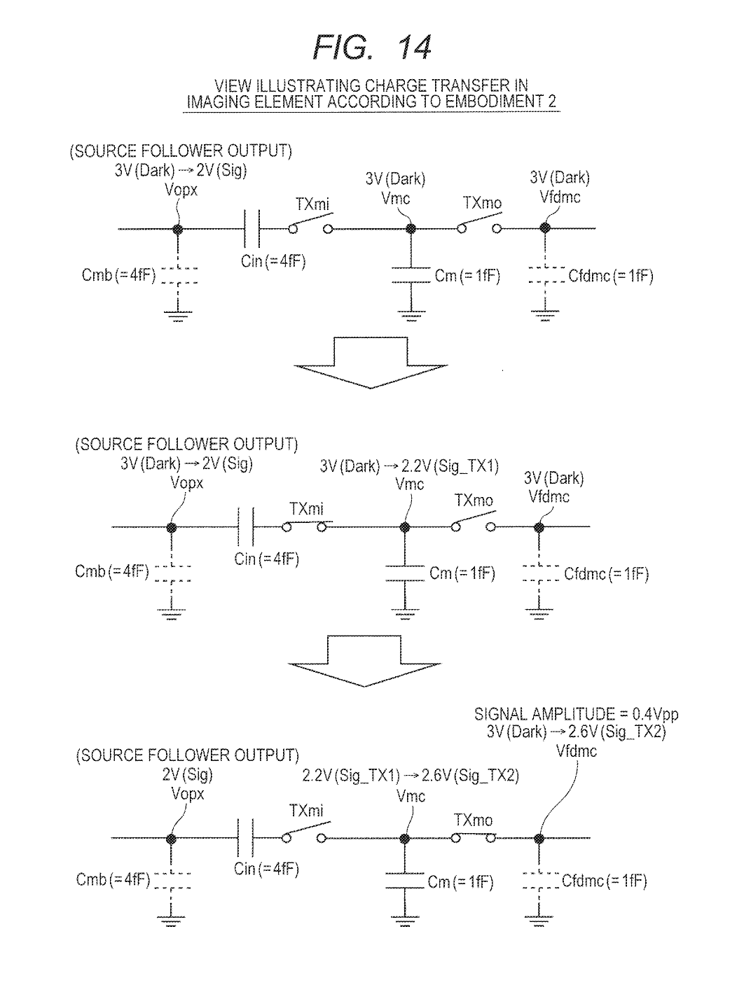

Referring to FIGS. 13 and 14, a description will be given of a quantity of the charges transferred to the floating diffusion FDmc. FIG. 13 is a view illustrating charge transfer when the configuration according to the comparative example is used.

When the charges are transferred along the path shown in FIG. 13, as a result of exposing the photodiode PD to light, the voltage in the photodiode PD drops from 3 V (shown as 3 V (Dark) in FIG. 13) to 2 V (shown as 2 V (Sig_gen) in FIG. 13). When the charges corresponding to the 2 V voltage are transferred to the storage capacitance, the voltage Vmc in the storage capacitance drops from 3 V to 2.8 V (shown as 2.8 V (Sig_TX1) in FIG. 13). This is because, by turning ON the first transfer transistor Tr1, a capacitor resulting from the combination of the capacitance of the photodiode PD with the storage capacitance re-distributes the charges stored in the two capacitances such that the voltage in the storage capacitance is equal to the voltage in the photodiode PD.

Then, by turning OFF the first transfer transistor Tr1 and turning ON the second transfer transistor Tr2, the charges stored in the storage capacitance are transferred to the floating diffusion. At this time, the voltage Vfdmc in the floating diffusion drops from 3 V to 2.84 V (shown as 2.84 V (Sig_TX2) in FIG. 13). This is because, by turning ON the second transfer transistor Tr2, the capacitor resulting from the combination of the storage capacitance with the capacitance of the floating diffusion re-distributes the charges stored in the two capacitances such that the voltage in the storage capacitance is equal to the voltage in the floating diffusion Cfdmc.

Thus, in the imaging element according to the comparative example, the voltage finally amplified by the source follower circuit is 0.16 Vpp, which is smaller than a voltage difference of 1 V resulting from the exposure of the photodiode PD to light.

FIG. 14 shows a view illustrating charge transfer in the imaging element 15 according to Embodiment 2. In FIG. 14, the parasitic capacitance Cmb of the micro bump is shown. In FIG. 14, as the reset voltage which provides the dark level, 3 V (shown as 3 V (Dark) in FIG. 14) is used. Also, in the example shown in FIG. 14, it is assumed that the parasitic capacitance Cmb of the micro bump is 4 fF, the coupling capacitance Cin is 4 fF, the memory capacitance Cm is 1 fF, and the parasitic capacitance Cfdmc serving as the floating diffusion FDmc is 1 fF.

As shown in FIG. 14, in the imaging element 15 according to Embodiment 2, the light detection circuit 40 outputs the first imaging signal voltage Vopx from the source follower circuit. Accordingly, when the first imaging signal voltage Vopx drops from 3 V to 2 V (shown as 2 V (Sig) in FIG. 14) as a result of the exposure, the voltage difference between the both ends of the coupling capacitance Cin temporarily changes from 0 V to 1 V. The voltage difference decreases to 0. 2 V as a result of the re-distribution of the charges between the memory capacitance Cm and the coupling capacitance Cin which is performed until the stored voltage Vmc becomes constant. In the example shown in FIG. 14, the stored voltage Vmc after the re-distribution of the charges is performed is 2.2 V (shown as 2.2 V (Sig_TX1) in FIG. 14). This is because the stored voltage Vmc is determined on the basis of a voltage obtained by dividing the voltage difference resulting from a change in the first imaging signal voltage Vopx on the basis of the capacitance ratio between the capacitance value of the coupling capacitance Cin and the capacitance value of the memory capacitance Cm. More specifically, a voltage when the voltage difference (1 V) in the first imaging signal voltage Vops is divided by the capacitance value (4 fF) of the coupling capacitance Cin and the capacitance value (1 fF) of the memory capacitance Cm and stored is 0.2 V. The stored voltage Vmc is a voltage calculated by adding the first imaging signal voltage Vopx at this time to 0.2 V.

In the example shown in FIG. 14, when charges are transferred from the memory capacitance Cm to the floating diffusion FDmc, the voltage Vfdmc in the floating diffusion FDmc changes from 3 V to 2.6 V (shown as 2.6 V (Sig_TX2 in FIG. 14). This is because, by turning ON the output transfer transistor 52, the memory capacitance Cm and the parasitic capacitance Cfdmc serving as the floating diffusion FDmc are combined with each other and, due to the combined capacitance, the charges stored in the two capacitances are re-distributed such that the stored voltage Vmc in the memory capacitance Cm is equal to the voltage Vfdmc in the floating diffusion FDmc.

Thus, in the imaging element 15 according to Embodiment 2, the light detection circuit 40 outputs the first imaging signal voltage Vopx from the source follower circuit. In addition, by providing the coupling capacitance Cin, the amplitude of the voltage to be amplified by the amplification transistor 54 becomes 0.4 Vpp, which is larger than in the imaging element according to the comparative example.

Also, in the imaging element 15 according to Embodiment 1, the first imaging signal voltage Vopx output from the source follower circuit of the light detection circuit 40 is stored in the memory capacitance Cm via the coupling capacitance Cin. This allows the offset voltage generated in the source follower circuit of the light detection circuit 40 according to Embodiment 1 to be removed using the coupling capacitance Cin and allows only the voltage difference component of the first imaging signal voltage Vopx resulting from the exposure to be stored in the memory capacitance Cm. That is, the imaging element 15 according to Embodiment 2 can output the second imaging signal voltage Vo1 unaffected by the offset noise generated in the source follower circuit of the light detection circuit 40.

### Embodiment 3

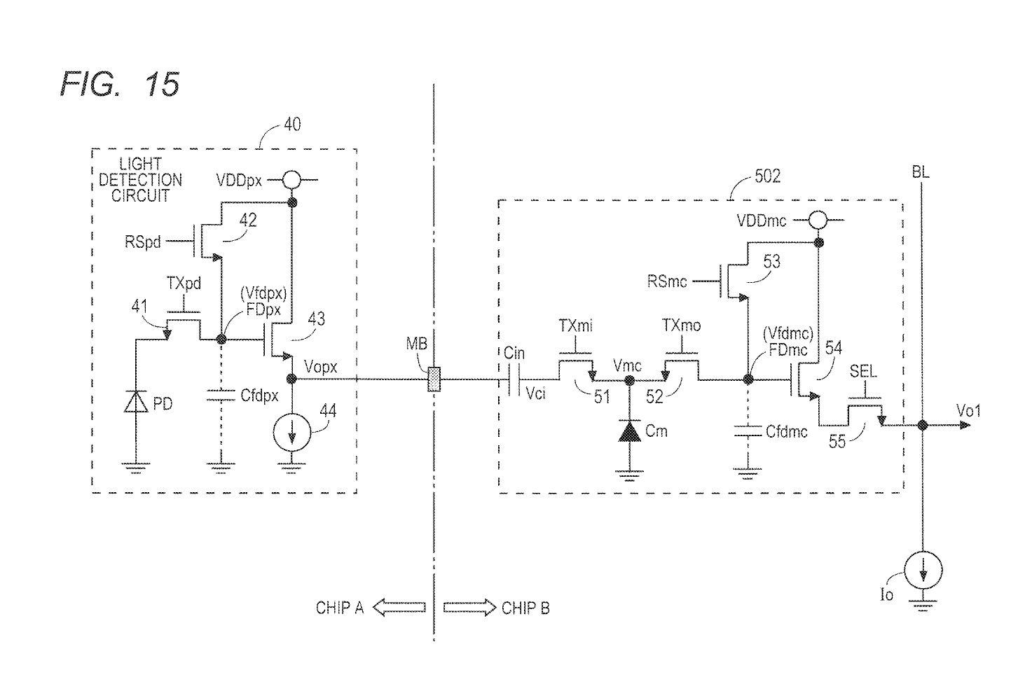

In Embodiment 3, a description will be given of a pixel value storage circuit 502 as another form of the pixel value storage circuit 501 according to Embodiment 2. FIG. 15 shows a circuit diagram illustrating the light detection circuit 40 and the pixel value storage circuit 502 in the imaging element 15 according to Embodiment 3. Note that, in the description of Embodiment 3, the same components as those described in Embodiments 1 and 2 are denoted by the same reference numerals as used in Embodiments 1 and 2 and a description thereof is omitted.

As shown in FIG. 15, the pixel value storage circuit 502 according to Embodiment 3 is obtained by using a fully depleted capacitance as the memory capacitance Cm of the pixel value storage circuit 501 according to Embodiment 2. The fully depleted capacitance uses a depletion layer formed in the PN junction portion of a diode as a capacitor. Accordingly, in FIG. 15, an anode is coupled as the memory capacitance Cm to a grounding wire, while a cathode is coupled to the source of the input transfer transistor 51 and to the source of the output transfer transistor 52.

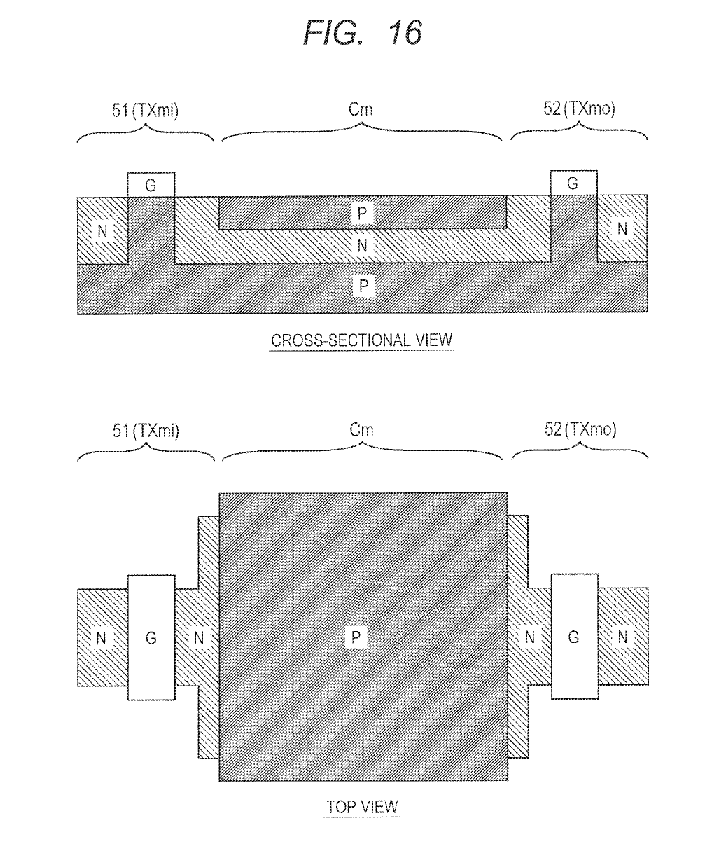

A description will be given herein of a structure of the diode used as the memory capacitance Cm. FIG. 16 shows a cross-sectional view (upper drawing) and a top view (lower drawing) of a semiconductor chip illustrating a structure of the pixel value storage capacitance Cm used in the imaging element 15 according to Embodiment 3.

As shown in the upper drawing of FIG. 16, in the pixel value storage circuit 50, the input transfer transistor 51, the memory capacitance Cm, and the output transfer transistor 52 are formed over a first-conductivity-type semiconductor substrate (e.g., a P-type semiconductor layer hereinafter referred to as a P-sub substrate). To the P-sub substrate, the grounding voltage is given. The memory capacitance Cm has, over the P-sub substrate, a second-conductivity-type first diffusion region (e.g., N-type diffusion region) and a first-conductivity-type second diffusion region (e.g., P-type diffusion region) formed in a layer above the N-type diffusion region. Each of the drains of the input transfer transistor 51 and the output transfer transistor 52 is formed of the N-type diffusion region formed over the P-sub substrate. As each of the sources of the input transfer transistor 51 and the output transfer transistor 52, the N-type diffusion region formed as the memory capacitance Cm is used. It is also possible to form a P-well layer over an N-sub substrate and use the P-well layer as the P-sub substrate shown in FIG. 16. It is assumed herein that the first conductivity type is the P-type and the second conductivity type is the N-type. However, it is also possible that the first conductivity type is the N-type and the second conductivity type is the P-type.

By forming the input transfer transistor 51, the memory capacitance Cm, and the output transfer transistor 52 into a configuration as shown in FIG. 16, the P-sub substrate and the P-type diffusion region serve as the anode of the diode forming the memory capacitance Cm, while the N-type diffusion region serves as the cathode of the diode. By applying a voltage to the cathode, a depletion layer is formed in the region of the memory capacitance Cm which is in the vicinity of the P-sub substrate and the P-type diffusion region to function as a capacitance. Two depletion layers, which are the depletion layer formed between the P-sub substrate and the N-type diffusion layer region and the depletion layer formed between the P-type diffusion region and the N-type diffusion layer region, join together at a voltage (PDVdep) determined by manufacturing conditions to form one depletion layer. This fully depletes the N-type diffusion region interposed between the P-sub substrate and the P-type diffusion region. When the N-type diffusion region is fully depleted, the voltage at the both ends of the capacitance is prevented from increasing to a value not less than PDVdep so that the voltage at the time of resetting (dark level voltage of the stored voltage Vmc) is PDVdep.

As shown in the lower drawing of FIG. 16, the diode used as the memory capacitance Cm is formed to have a width (length in the vertical direction of the lower drawing of FIG. 16) larger than the gate widths of the input transfer transistor 51 and the output transfer transistor 52. By thus shaping the diode, the capacitance value of the memory capacitance Cm can be increased with a high area efficiency. As also shown in FIG. 16, in the imaging element 15 according to Embodiment 3, the source of the input transfer transistor 51 and the N-type diffusion region of the memory capacitance Cm are formed in the continuous integrated region. Also, in the imaging element 15 according to Embodiment 3, the source of the output transfer transistor 52 and the N-type diffusion region of the memory capacitance Cm are formed in the continuous integrated region.

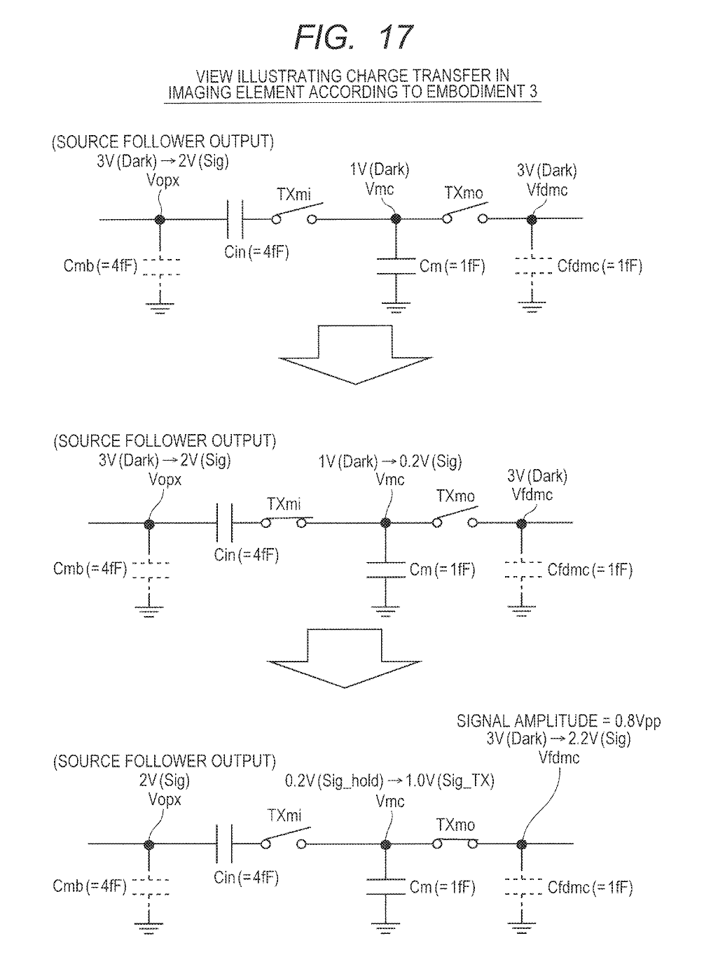

Subsequently, FIG. 17 shows a view illustrating charge transfer in the imaging element 15 according to Embodiment 3. In FIG. 17, the parasitic capacitance Crab of the micro bump is shown. In FIG. 17, 3 V is used as the reset voltage which provides the dark level. In the example shown in FIG. 17, it is assumed that the parasitic capacitance Cmb of the micro bump is 4 fF, the memory capacitance Cm is 1 fF, and the parasitic capacitance Cfdmc serving as the floating diffusion FDmc is 1 fF. It is also assumed that a full depletion voltage which is generated when the memory capacitance Cm is fully depleted is 1 V. This is because, since the memory capacitance Cm is a junction capacitance in Embodiment 3, electron-hole pairs are generated in the depletion layer portion and a diffusion potential specific to a material is generated. When the semiconductor substrate is made of silicon (Si), the full depletion voltage thereof is about 1 V.

As shown in FIG. 17, when the fully depleted junction capacitance is used as the memory capacitance Cm, the dark level of the stored voltage Vmc is 1 V serving as the full depletion voltage. When the first imaging signal voltage Vopx drops from 3 V to 2 V as a result of exposure, the voltage difference between the both ends of the coupling capacitance Cin temporarily changes from 2 V to 1 V. The voltage difference returns to 1.8 V as a result of the re-distribution of the charges between the memory capacitance Cm and the coupling capacitance Cin which is performed until the stored voltage Vmc becomes constant. In the example shown in FIG. 14, the stored voltage Vmc after the charge re-distribution is performed is 0.2 V. This is because the stored voltage Vmc is determined on the basis of a voltage obtained by dividing the voltage difference resulting from a change in the first imaging signal voltage Vopx on the basis of the capacitance ratio between the capacitance value of the coupling capacitance Cin and the capacitance value of the memory capacitance Cm. That is, when an amount of change in the first imaging signal voltage Vopx is ΔVopx, the capacitance value of the memory capacitance Cm is Cm, the capacitance value of the coupling capacitance Cin is Cin, the voltage at the both ends of the memory capacitance Cm before the change occurs in the first imaging signal voltage Vopx is VCm′, and the voltage at the both ends of the coupling capacitance Cin before the change occurs in the first imaging signal voltage Vopx is VCin′, the voltage at the both ends of the memory capacitance Cm is calculated to be VCm′−ΔVopx×(Cin/(Cin+Cm))=0.2 V, while the voltage at the both ends of the coupling capacitance Cin is calculated to be VCin−ΔVopx×(Cm/Cin Cm))=1. 8 V. Accordingly, in the example shown in FIG. 17, when the first imaging signal voltage Vopx drops from 3 V to 2 V as a result of the exposure, the stored voltage Vmc changes from 1 V to 0.2 V.

In the example shown in FIG. 17, when charges are transferred from the memory capacitance Cm to the floating diffusion FDmc, the voltage Vfdmc in the floating diffusion FDmc changes from 3 V to 2.2 V. This is because, by turning ON the output transfer transistor 52, the charges stored in the memory capacitance Cm are directly transferred to the floating diffusion FDmc. At this time, the stored voltage Vmc in the memory capacitance Cm is restored to the full depletion voltage.

A further detailed description will be given herein of charge transfer when the fully depleted capacitance is used as the memory capacitance Cm. In the case of using the fully depleted capacitance as the memory capacitance Cm, when the state in the upper drawing of FIG. 17 shifts to the state in the middle drawing of FIG. 17, charges move from the coupling capacitance Cin to the fully depleted memory capacitance Cm to be recombined with the holes forming the depletion layer in the memory capacitance Cm. That is, the stored voltage Vmc accordingly drops by the quantity of the recombined holes. Subsequently, when the state in the middle drawing of FIG. 17 shifts to the state in the lower drawing thereof, the charges recombined with the holes forming the depletion layer in the memory capacitance Cm move to the floating diffusion FDmc. The quantity of the charges which move at this time is such as to provide the quantity of holes equal to that which achieves the full depletion voltage (1 V) in the memory capacitance Cm, i.e., such as to cause a 0.8 V potential change in a 1 fF capacitance. Such movement of the charges is implemented by integrally forming the source of the input transfer transistor 51 with the N-type diffusion region of the memory capacitance Cm and by integrally forming the source of the output transfer transistor 52 with the N-type diffusion region of the memory capacitance Cm.

When the fully depleted junction capacitance is thus used as the memory capacitance Cm, as a result of allowing the light detection circuit 40 to output the first imaging signal voltage Vopx from the source follower circuit and providing the coupling capacitance Cin, the amplitude of the voltage to be amplified by the amplification transistor 54 is 0.8 Vpp, which is larger than in the example shown in FIG. 14.

Note that, in the example shown in FIG. 17, by reducing the capacitance value of the parasitic capacitance Cfdmc of the floating diffusion FDmc from 1 fF to 0.5 fF, the signal amplitude can be increased to 1.6 Vpp.

Thus, in the imaging element 15 according to Embodiment 3, by using the fully depleted junction capacitance as the memory capacitance Cm, it is possible to prevent a reduction in the quantity of the charges transferred to the floating diffusion FDmc. Thus, in the imaging element 15 according to Embodiment 3, it is possible to prevent a reduction in the quantity of the charges transferred to the floating diffusion FDmc of the pixel value storage circuit 502 and output the second imaging signal voltage Vo1 having a high S/N ratio.

When the fully depleted junction capacitance is used as the memory capacitance Cm, the stored voltage Vmc when the memory capacitance Cm is reset is the full depletion voltage so that the influence of reset noise caused by a resetting operation is not left in the stored voltage Vmc at the time of resetting. As a result, in the pixel value storage circuit 502 according to Embodiment 3, the reset noise caused on the resetting of the floating diffusion FDmc equally affects the dark level signal and the second imaging signal voltage Vo1. Accordingly, in the imaging element 15 according to Embodiment 3, the CDS circuit 34 in the stage subsequent to that of the pixel value storage circuit 502 allows the reset noise caused by the operation of resetting the floating diffusion FDmc to be accurately cancelled out.

### Embodiment 4

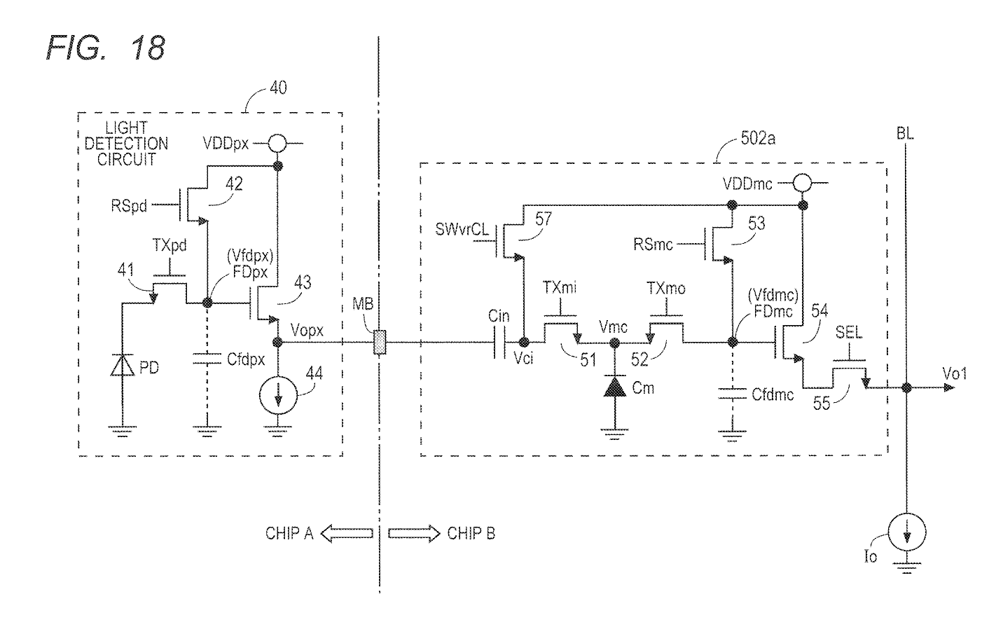

In Embodiment 4, a description will be given of a pixel value storage circuit 502a as a modification of the pixel value storage circuit 50. FIG. 18 shows a circuit diagram illustrating the light detection circuit 40 and the pixel value storage circuit 502a in the imaging element 15 according to Embodiment 4. Note that, in the description of Embodiment 4, the same components as those described in Embodiments 1 to 3 are denoted by the same reference numerals as used in Embodiments 1 to 3 and a description thereof is omitted.

As shown in FIG. 18, the pixel value storage circuit 502a is obtained by adding a reset transistor 57 to the pixel value storage circuit 502. The reset transistor 57 resets the stored input voltage Vci to the reset voltage in response to a coupling capacitance reset control signal SWvrCL. The reset voltage to which the stored input voltage Vci is reset is the storage circuit power supply voltage VDDmc in the present embodiment.

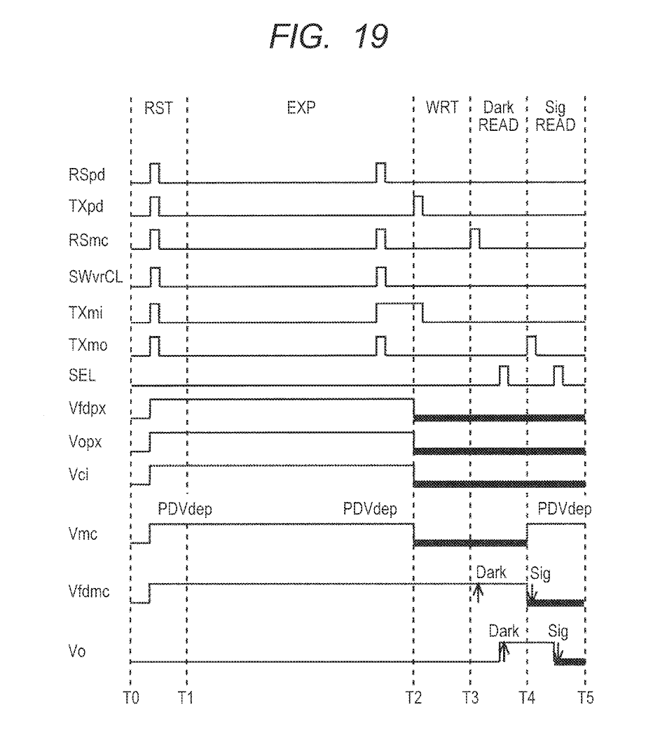

A description will be given herein of the operations of the light detection circuit 40 and the pixel value storage circuit 502a in the imaging element 15 according to Embodiment 4. FIG. 19 shows a timing chart illustrating the operations of the light detection circuit 40 and the pixel value storage circuit 502a in the imaging element 15 according to Embodiment 4. The operations shown in FIG. 19 are obtained by causing the light detection circuit 40 and the pixel value storage circuit 502a according to Embodiment 4 to perform the same operations as those of the light detection circuit 40 and the pixel value storage circuit 50 according to Embodiment 1.

As shown in FIG. 19, the light detection circuit 40 and the pixel value storage circuit 502a according to Embodiment 4 are obtained by adding an operation of resetting the stored input voltage Vo1 based on the coupling capacitance reset control signal SWvrCL to the light detection circuit 40 and the pixel value storage circuit 50 according to Embodiment 1. Specifically, in the light detection circuit 40 and the pixel value storage circuit 502a according to Embodiment 4, during the reset period RST between the timings T0 and T1 and the exposure period EXP, a HIGH pulse is input as the coupling capacitance reset control signal SWvrCL to give the reset voltage to the stored input voltage Vci.

As described above, in the pixel value storage circuit 502a according to Embodiment 4, the reset voltage is given to the other end of the coupling capacitance Cin without passing the reset voltage through the memory capacitance Cm. As a result, in the pixel value storage circuit 502a according to Embodiment 4, it is possible to reduce a reset time associated with the coupling capacitance Cin. Since the reset time is reduced, in the imaging element 15 according to Embodiment 4, the time required for one readout operation is reduced and therefore a frame rate can be increased.

### Embodiment 5

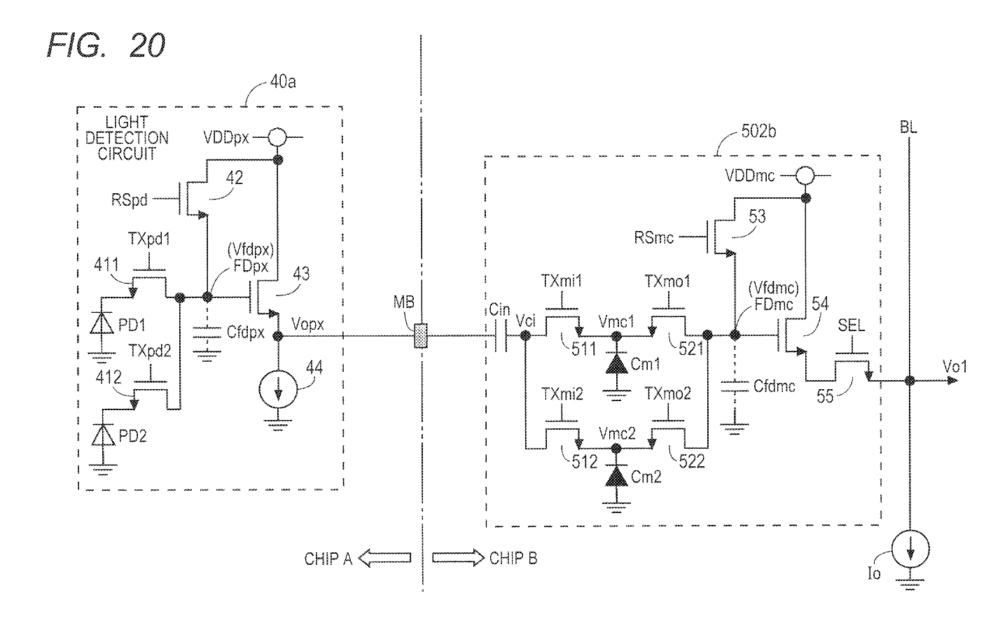

In Embodiment 5, a description will be given of a light detection circuit 40a as a modification of the light detection circuit 40 and a pixel value storage circuit 502b as a modification of the pixel value storage circuit 502. FIG. 20 shows a circuit diagram illustrating the light detection circuit 40a and the pixel value storage circuit 502b in the imaging element 15 according to Embodiment 5. Note that, in the description of Embodiment 5, the same components as those described in Embodiments 1 to 3 are denoted by the same reference numerals as used in Embodiments 1 to 3 and a description thereof is omitted.

As shown in FIG. 20, the light detection circuit 40a has two pairs of the photodiodes PD and transfer transistors for the one amplification transistor 43. In FIG. 20, the circuit is configured such that the charges generated in a photodiode PD1 are transferred to the floating diffusion FDpx via a transfer transistor 411 and the charges generated in a photodiode PD2 are transferred to the floating diffusion FDpx via a transfer transistor 412.

As also shown in FIG. 20, the pixel value storage circuit 502b is obtained by adding another set of the memory capacitance Cm, the input transfer transistor 51, and the output transfer transistor 52 to the pixel value storage circuit 502. Specifically, in the pixel value storage circuit 502b, between the coupling capacitance Cin and the floating diffusion FDmc, a first storage circuit including an input transfer transistor 511, a memory capacitance Cm1, and an output transfer transistor 521 and a second storage circuit including an input transfer transistor 512, a memory capacitance Cm2, and an output transfer transistor 522 are coupled in parallel to each other. Note that the coupling between the elements in each of the storage circuits is the same as that in the storage circuit including the input transfer transistor 51, the memory capacitance Cm, and the output transfer transistor 52.

That is, in the imaging element 15 according to Embodiment 5, the light detection circuit 40a has the plurality of pairs of the photodiodes PD and the transfer transistors 41, and the pixel value storage circuit 502b has the same number of sets of the memory capacitances Cm, the input transfer transistors 51, and the output transfer transistors 52 as that of the pairs of the photodiodes PD and the transfer transistors 41 of the light detection circuit 40a.

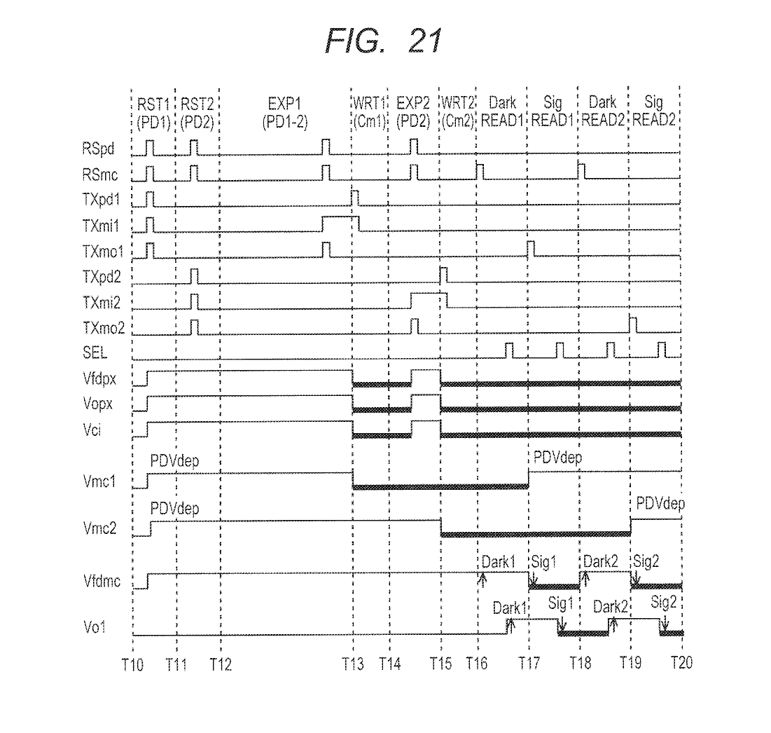

Subsequently, a description will be given of the operations of the light detection circuit 40a and the pixel value storage circuit 502b according to Embodiment 5. FIG. 21 shows a timing chart illustrating the operations of the light detection circuit and the pixel value storage circuit in the imaging element according to Embodiment 5.

As shown in FIG. 21, during a first reset period RST1 (between T10 and T11), HIGH pulses are given as the reset control signal RSpd, the reset control signal RSmc, a transfer control signal TXpd1, a storage control signal TXmi1, and the read control signal TXmo1 to reset the photodiode PD1, the floating diffusion FDpx, the floating diffusion FDmc, the memory capacitance Cm1, and the parasitic capacitance of the micro bump MB. Also, during the first reset period RS1, at the time when the transfer control signal TXpd1 shifts to the LOW level, the exposure of the photodiode PD1 to light is initiated.

Subsequently, during a second reset period RST2 (between T11 and T12), HIGH pulses are given as the reset control signal RSpd, the reset control signal RSmc, a transfer control signal TXpd2, a storage control signal TXmi2, and a read control signal TXmo2 to reset the photodiode PD2, the floating diffusion FDpx, the floating diffusion FDmc, the memory capacitance Cm2, and the parasitic capacitance of the micro bump MB. Also, during the second reset period RST2, at the time when the transfer control signal TXpd2 shifts to the LOW level, the exposure of the photodiode PD2 to light is initiated.

Subsequently, during a first exposure period EXP1 (between T12 and T13), each of the photodiodes PD1 and PD2 is exposed to light. During the first exposure period EXP1, HIGH pulses are given as the reset control signal RSpd, the reset control signal RSmc, the storage control signal TXmi1, and the read control signal TXmo1 to reset the floating diffusion FDpx, the floating diffusion FDmc, and the memory capacitance Cm1.

Subsequently, during a first memory write period WRT1 (between T13 and T14), a HIGH pulse is given as the transfer control signal TXpd1 to transfer the charges generated in the photodiode PD1 to the floating diffusion FDpx and generate the first imaging signal voltage Vopx on the basis of the voltage in the floating diffusion FDpx. Also, during the first memory write period WRT1, a HIGH pulse is given as the storage control signal TXmi1 to store the charges generated on the basis of the first imaging signal voltage Vopx in the memory capacitance Cm1.

Subsequently, during a second exposure period EXP2 (between T14 and T15), the photodiode PD2 is exposed to light. During the second exposure period EXP2, HIGH pulses are given as the reset control signal RSpd, the reset control signal RSmc, the storage control signal TXmi2, and the read control signal TXmo2 to reset the floating diffusion FDpx, the floating diffusion FDmc, and the memory capacitance Cm2.

Subsequently, during a second memory write period WRT2 (between T15 and T16), a HIGH pulse is given as the transfer control signal TXpd2 to transfer the charges generated in the photodiode PD2 to the floating diffusion FDpx and generate the first imaging signal voltage Vopx on the basis of the voltage in the floating diffusion FDpx. Also, during the second memory write period WRT2, a HIGH pulse is given as the storage control signal TXmi2 to store the charges generated on the basis of the first imaging signal voltage Vopx in the memory capacitance Cm2.

Subsequently, during a first dark level read period DarkREAD1 (between T16 and T17), a HIGH pulse is given as the reset control signal RSmc to place the floating diffusion FDmc at the reset voltage. Also, during the first dark level read period DarkREAD1, a HIGH pulse is given as the selection signal SEL to output the dark level signal generated by the amplification transistor 54 on the basis of the reset voltage to the bit line BL.

Subsequently, during a first imaging signal read period SigREAD1 (between T17 and T18), a HIGH pulse is given as the read control signal TXmo1 to transfer the charges stored in the memory capacitance Cm1 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during a second dark level read period DarkREAD2 (between T18 and T19), a HIGH pulse is given as the reset control signal RSmc to place the floating diffusion FDmc at the reset voltage. Also, during the second dark level read period DarkREAD2, a HIGH pulse is given as the selection signal SEL to output the dark level signal generated by the amplification transistor 54 on the basis of the reset voltage to the bit line BL.

Subsequently, during a second imaging signal read period SigREAD2 (between T19 and T20), a HIGH pulse is given as the read control signal TXmo2 to transfer the charges stored in the memory capacitance Cm2 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

As described above, in the imaging element 15 according to Embodiment 5, in the light detection circuit 40a, the two photodiodes PD are provided for one pair of the reset transistor and the amplification transistor 43. Accordingly, in the imaging element 15 according to Embodiment 5, by reducing the number of the transistors corresponding to each one of the photodiodes and thus reducing the pixel size, it is possible to increase the number of pixels per area.

### Embodiment 6

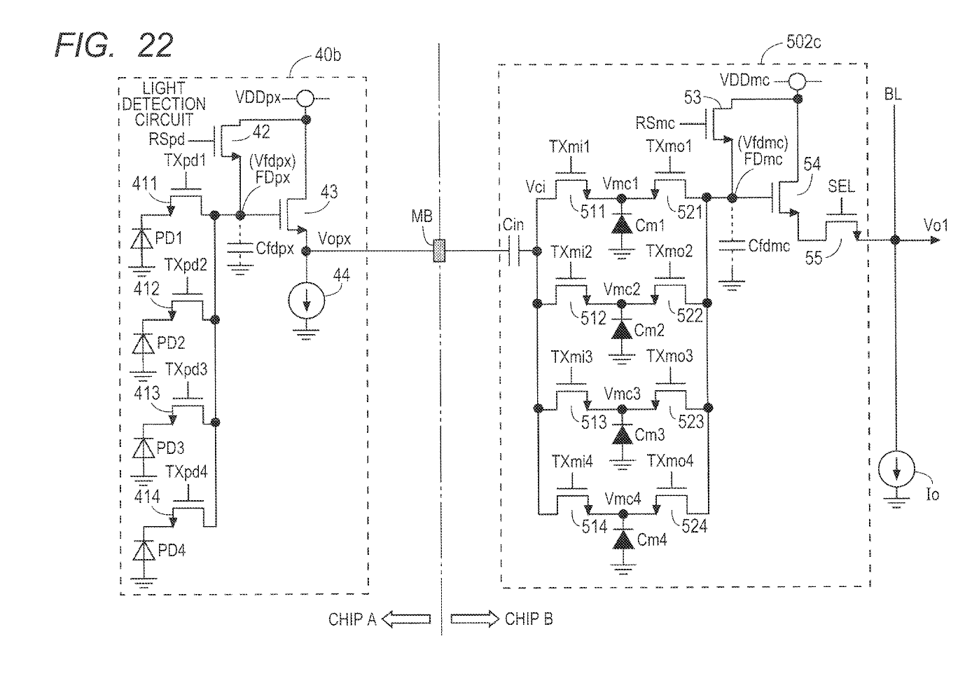

In Embodiment 6, a description will be given of a light detection circuit 40b as a modification of the light detection circuit 40 and a pixel value storage circuit 502c as a modification of the pixel value storage circuit 502. FIG. 22 shows a circuit diagram illustrating the light detection circuit 40b and the pixel value storage circuit 502c in the imaging element 15 according to Embodiment 6. Note that, in the description of Embodiment 6, the same components as those described in Embodiments 1 to 3 are denoted by the same reference numerals as used in Embodiment s 1 to 3 and a description thereof is omitted.

As shown in FIG. 22, the light detection circuit 40b has four pairs of the photodiodes PD and the transfer transistors for the one amplification transistor 43. In FIG. 22, the charges generated in the photodiode PD1 are transferred to the floating diffusion FDpx via the transfer transistor 411. Also, the charges generated in the photodiode PD2 are transferred to the floating diffusion FDpx via the transfer transistor 412. Also, the charges generated in a photodiode PD3 are transferred to the floating diffusion FDpx via a transfer transistor 413. Also, the charges generated in a photodiode PD4 are transferred to the floating diffusion FDpx via a transfer transistor 414.

As also shown in FIG. 22, the pixel value storage circuit 502c is obtained by adding three more sets of the memory capacitances Cm, the input transfer transistors 51, and the output transfer transistors 52 to the pixel value storage circuit 50. Specifically, in the pixel value storage circuit 502c, between the coupling capacitor Cin and the floating diffusion FDmc, first to fourth storage circuits are coupled in parallel to each other. The first storage circuit includes the input transfer transistor 511, the memory capacitance Cm1, and the output transfer transistor 521. The second storage circuit includes the input transfer transistor 512, the memory capacitance Cm2, and the output transfer transistor 522. The third storage circuit includes an input transfer transistor 513, a memory capacitance Cm3, and an output transfer transistor 523. The fourth storage circuit includes an input transfer transistor 514, a memory capacitance Cm4, and an output transfer transistor 524. Note that the coupling between the elements in each of the storage circuits is the same as that in the storage circuit including the input transfer transistor 51, the memory capacitance Cm, and the output transfer transistor 52.

That is, in the imaging element 15 according to Embodiment 6, the light detection circuit 40b has the plurality of pairs of the photodiodes PD and the transfer transistors 41, while the pixel value storage circuit 502c has the same number of sets of the memory capacitances Cm, the input transfer transistors 51, and the output transfer transistors 52 as the number of the pairs of the photodiodes PD and the transfer transistors 41 of the light detection circuit 40b.

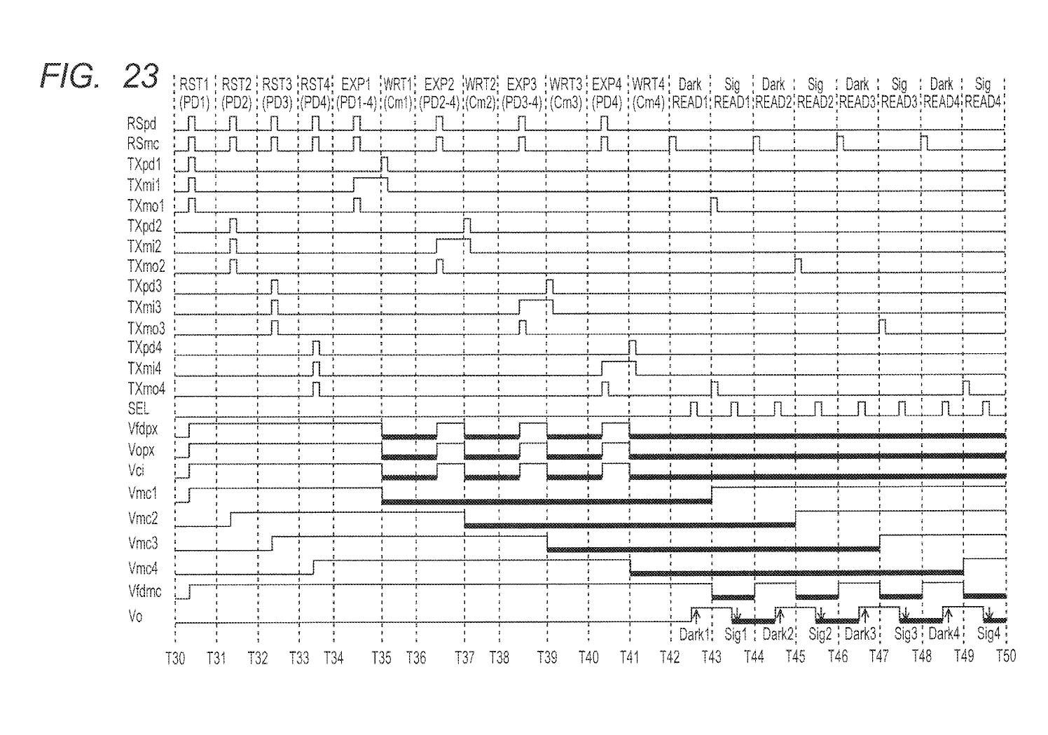

Subsequently, a description will be given of the operations of the light detection circuits 40b and the pixel value storage circuits 502c according to Embodiment 6. FIG. 23 shows a timing chart illustrating the operations of the light detection circuits 40b and the pixel value storage circuits 502c in the imaging element 15 according to Embodiment 6.

As shown in FIG. 23, during the first reset period RST1 (between T30 and T31), HIGH pulses are given as the reset control signal RSpd, the reset control signal RSmc, the transfer control signal TXpd1, the storage control signal TXmi1, and the read control signal TXmo1 to reset the photodiode PD1, the floating diffusion FDpx, the floating diffusion FDmc, the memory capacitance Cm1, and the parasitic capacitance of the micro bump MB. Also, during the first reset period RST1, at the time when the transfer control signal TXpd1 shifts to the LOW level, the exposure of the photodiode PD1 to light is initiated.

Subsequently, during the second reset period RST2 (between T31 and T32), HIGH pulses are given as the reset control signal RSpd, the reset control signal RSmc, the transfer control signal TXpd2, the storage control signal TXmi2, and the read control signal TXmo2 to reset the photodiode PD2, the floating diffusion FDpx, the floating diffusion FDmc, the memory capacitance Cm2, and the parasitic capacitance of the micro bump MB. Also, during the second reset period RST2, at the time when the transfer control signal TXpd2 shifts to the LOW level, the exposure of the photodiode PD2 to light is initiated.

Subsequently, during a third reset period RST3 (between T32 and T33), HIGH pulses are given as the reset control signal RSpd, the reset control signal RSmc, a transfer control signal TXpd3, a storage control signal TXmi3, and a read control signal TXmo3 to reset the photodiode PD3, the floating diffusion FDpx, the floating diffusion FDmc, the memory capacitance Cm3, and the parasitic capacitance of the micro bump MB. Also, during the third reset period RST3, at the time when the transfer control signal TXpd 3 shifts to the LOW level, the exposure of the photodiode PD3 to light is initiated.

Subsequently, during a fourth reset period RST4 (between T33 and T34), HIGH pulses are given as the reset control signal RSpd, the reset control signal RSmc, a transfer control signal TXpd4, a storage control signal TXmi4, and a read control signal TXmo4 to reset the photodiode PD4, the floating diffusion FDpx, the floating diffusion FDmc, the memory capacitance Cm4, and the parasitic capacitance of the micro bump MB. Also, during the fourth reset period RST4, at the time when the transfer control signal TXpd4 shifts to the LOW level, the exposure of the photodiode PD 4 to light is initiated.

Subsequently, during the first exposure period EXP1 (between T34 and T35), each of the photodiodes PD1 to PD4 is exposed to light. Also, during the first exposure period EXP1, HIGH pulses are given as the reset control signal RSpd, the reset control signal RSmc, the storage control signal TXmi1, and the read control signal TXmo1 to reset the floating diffusion FDpx, the floating diffusion FDmc, and the memory capacitance Cm1.

Subsequently, during the first memory write period WRT1 (between T35 and T36), a HIGH pulse is given as the transfer control signal TXpd1 to transfer the charges generated in the photodiode PD1 to the floating diffusion FDpx and generate the first imaging signal voltage Vopx on the basis of the voltage in the floating diffusion FDpx. Also, during the first memory write period WRT1, a HIGH pulse is given as the storage control signal TXmi1 to store the charges generated on the basis of the first imaging signal voltage Vopx in the memory capacitance Cm1.

Subsequently, during the second exposure period EXP2 (between T36 and T37), each of the photodiodes PD2 to PD4 is exposed to light. Also, during the second exposure period EXP2, HIGH pulses are given as the reset control signal RSpd, the reset control signal RSmc, the storage control signal TXmi2, and the read control signal TXmo2 to reset the floating diffusion FDpx, the floating diffusion FDmc, and the memory capacitance Cm2.

Subsequently, during the second memory write period WRT2 (between T37 and T38), a HIGH pulse is given as the transfer control signal TXpd2 to transfer the charges generated in the photodiode PD2 to the floating diffusion FDpx and generate the first imaging signal voltage Vopx on the basis of the voltage in the floating diffusion FDpx. Also, during the second memory write period WRT2, a HIGH pulse is given as the storage control signal TXmi2 to store the charges generated on the basis of the first imaging signal voltage Vopx in the memory capacitance Cm2.

Subsequently, during a third exposure period EXP3 (between T38 and T39), both of the photodiodes PD3 and PD4 are exposed to light. Also, during the third exposure period EXP3, HIGH pulses are given as the reset control signal RSpd, the reset control signal RSmc, the storage control signal TXmi3, and the read control signal TXmo3 to reset the floating diffusion FDpx, the floating diffusion FDmc, and the memory capacitance Cm3.

Subsequently, during a third memory write period WRT3 (between T39 and T40), a HIGH pulse is given as the transfer control signal TXpd3 to transfer the charges generated in the photodiode PD3 to the floating diffusion FDpx and generate the first imaging signal voltage Vopx on the basis of the voltage in the floating diffusion FDpx. Also, during the third memory write period WRT3, a HIGH pulse is given as the storage control signal TXmi3 to store the charges generated on the basis of the first imaging signal voltage Vopx in the memory capacitance Cm3.

Subsequently, during a fourth exposure period EXP4 (between T40 and T41), the photodiode PD4 is exposed to light. Also, during the fourth exposure period EXP4, HIGH pulses are given as the reset control signal RSpd, the reset control signal RSmc, the storage control signal TXmi4, and the read control signal TXmo4 to reset the floating diffusion FDpx, the floating diffusion FDmc, and the memory capacitance Cm4.

Subsequently, during a fourth memory write period WRT4 (between T41 and T42), a HIGH pulse is given as the transfer control signal TXpd4 to transfer the charges generated in the photodiode PD4 to the floating diffusion FDpx and generate the first imaging signal voltage Vopx on the basis of the voltage in the floating diffusion FDpx. Also, during the fourth memory write period WRT4, a HIGH pulse is given as the storage control signal TXmi4 to store the charges generated on the basis of the first imaging signal voltage Vopx in the memory capacitance Cm4.

Subsequently, during the first dark level read period DarkREAD1 (between T42 and T43), a HIGH pulse is given as the reset control signal RSmc to place the floating diffusion FDmc at the reset voltage. Also, during the first dark level read period DarkREAD1, a HIGH pulse is given as the selection signal SEL to output the dark level signal generated by the amplification transistor 54 on the basis of the reset voltage to the bit line BL.

Subsequently, during the first imaging signal read period SigREAD1 (between T43 and T44), a HIGH pulse is given as the read control signal TXmo1 to transfer the charges stored in the memory capacitance Cm1 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during the second dark level read period DarkREAD2 (between T44 and T45), a HIGH pulse is given as the reset control signal RSmc to place the floating diffusion FDmc at the reset voltage. Also, during the second dark level read period DarkREAD2, a HIGH pulse is given as the selection signal SEL to output the dark level signal generated by the amplification transistor 54 on the basis of the reset voltage to the bit line BL.

Subsequently, during the second imaging signal read period SigREAD2 (between T45 and T46), a HIGH pulse is given as the read control signal TXmo2 to transfer the charges stored in the memory capacitance Cm2 to the floating diffusion FDmc. In addition, the amplification transistor 54 outputs the second imagine signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during a third dark level read period DarkREAD3 (between T46 and T47), a HIGH pulse is given as the reset control signal RSmc to place the floating diffusion FDmc at the reset voltage. Also, during the third dark level read period DarkREAD3, a HIGH pulse is given as the selection signal SEL to output the dark level signal generated by the amplification transistor 54 on the basis of the reset voltage to the bit line BL.

Subsequently, during a third imaging signal read period SigREAD3 (between T47 and T48), a HIGH pulse is given as the read control signal TXmo3 to transfer the charges stored in the memory capacitance Cm3 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during a fourth dark level read period DarkREAD4 (between T48 and T49), a HIGH pulse is given as the reset control signal RSmc to place the floating diffusion FDmc at the reset voltage. Also, during the third dark level read period DarkREAD3, a HIGH pulse is given as the selection signal SEL to output the dark level signal generated by the amplification transistor 54 on the basis of the reset voltage to the bit line BL.

Subsequently, during a fourth imaging signal read period SigREAD4 (between T49 and T50), a HIGH pulse is given as the read control signal TXmo4 to transfer the charges stored in the memory capacitance Cm4 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

As described above, in the imaging element 15 according to Embodiment 6, in the light detection circuit 40a, the four photodiodes PD are provided for the one pair of the reset transistor 42 and the amplification transistor 43. Accordingly, in the imaging element 15 according to Embodiment 6, the number of the transistors corresponding to each one of the photodiodes can further be reduced than that in the imaging element 15 according to Embodiment 5. Also, in the imaging element 15 according to Embodiment 6, by reducing the pixel size compared to that in the imaging element 15 according to Embodiment 5, it is possible to increase the number of pixels per unit area.

### Embodiment 7

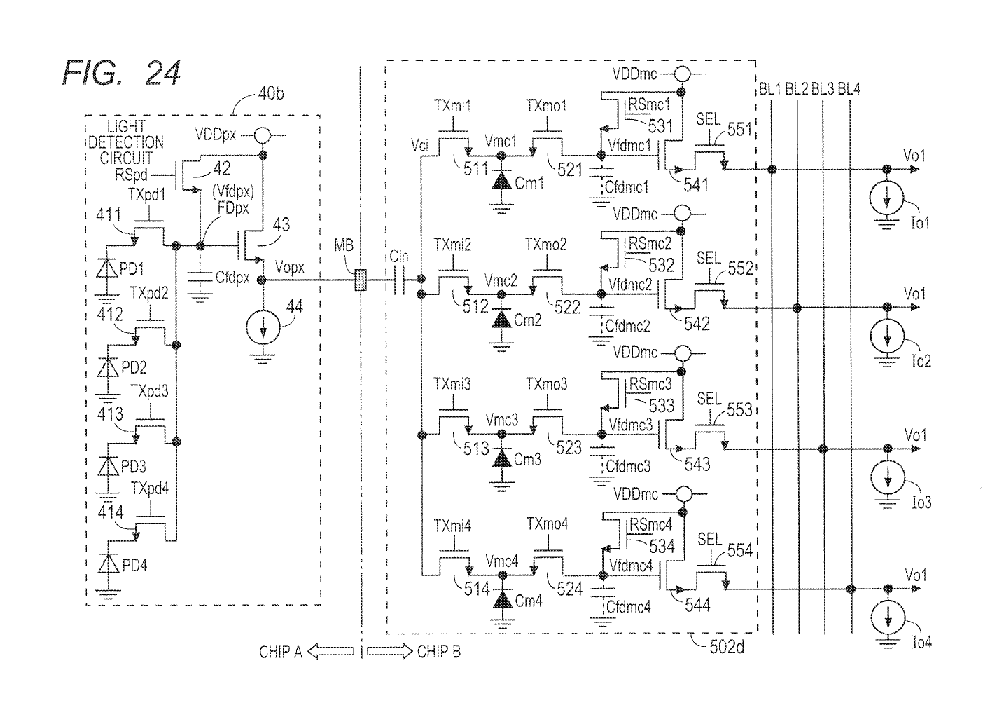

In Embodiment 7, a description will be given of a combination of the light detection circuit 40b and a pixel value storage circuit 502d as a modification of the pixel value storage circuit 502c. FIG. 24 shows a circuit diagram illustrating the light detection circuit 40b and the pixel value storage circuit 502d in the imaging element 15 according to Embodiment 7. Note that, in the description of Embodiment 7, the same components as those described in Embodiments 1 to 3 and 6 are denoted by the same reference numerals as used in Embodiments 1 to 3 and 6 and a description thereof is omitted.

As shown in FIG. 22, the pixel value storage circuit 502d is obtained by adding the reset transistor 53, the amplification transistor 54, and the selection transistor 55 to each set of the memory capacitance Cm, the input transfer transistor 51, and the output transfer transistor 52 of the pixel value storage circuit 502c. Specifically, in the pixel value storage circuit 502d, between the coupling capacitance Cin and the floating diffusion FDmc, the first to fourth storage circuits are coupled in parallel to each other. For the first storage circuit, a reset transistor 531, an amplification transistor 541, and a selection transistor 551 are provided. For the second storage circuit, a reset transistor 532, an amplification transistor 542, and a selection transistor 552 are provided. For the third storage circuit, a reset transistor 533, an amplification transistor 543, and a selection transistor 553 are provided. For the fourth storage circuit, a reset transistor 534, an amplification transistor 544, and a selection transistor 554 are provided. For the respective amplification transistors 541 to 544, bit lines independent of each other are provided. The coupling relations between the reset transistor 534, the amplification transistor 544, and the selection transistor 554 are the same as those between the reset transistor 53, the amplification transistor 54, and the selection transistor 55.

That is, in the imaging element 15 according to Embodiment 7, the light detection circuit 40b has the plurality of pairs of the photodiodes PD and the transfer transistors 41, while the pixel value storage circuit 502d has the same number of sets of the memory capacitances Cm, the input transfer transistors 51, the output transfer transistors 52, the second floating diffusions, the second reset transistors 53, and the second amplification transistors 55 as the number of the pairs of the photodiodes PD and the transfer transistors 41 of the light detection circuit 40b.

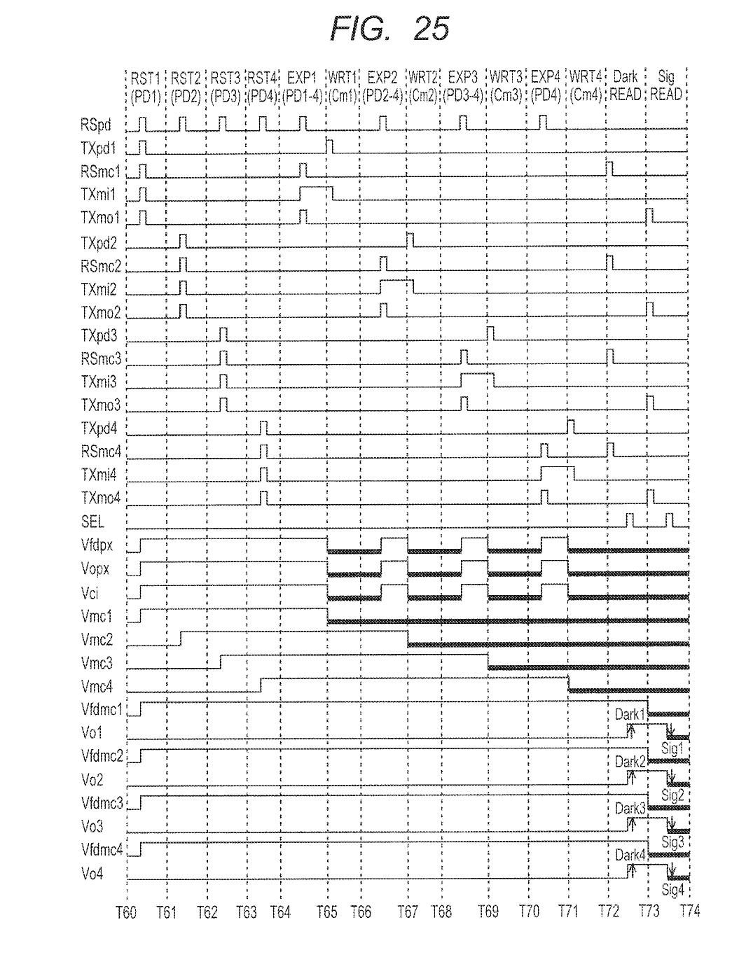

Subsequently, a description will be given of the operations of the light detection circuit 40b and the pixel value storage circuit 502d according to Embodiment 7. FIG. 25 shows a timing chart illustrating the operations of the light detection circuit 40b and the pixel value storage circuit 502d of the imaging element 15 according to Embodiment 7.

As shown in FIG. 25, during the first reset period RST1 (between T60 and T61), HIGH pulses are given as the reset control signal RSpd, a reset control signal RSmc1, the transfer control signal TXpd1, the storage control signal TXmi1, and the read control signal TXmo1 to reset the photodiode PD1, the floating diffusion FDpx, a floating diffusion FDmc1, the memory capacitance Cm1, and the parasitic capacitance of the micro bump MB. Also, during the first reset period RST1, at the time when the transfer control signal TXpd1 shifts to the LOW level, the exposure of the photodiode PD1 to light is initiated.

Subsequently, during the second reset period RST2 (between T61 and T62), HIGH pulses are given as the reset control signal RSpd, a reset control signal RSmc2, the transfer control signal TXpd2, the storage control signal TXmi2, and the read control signal TXmo2 to reset the photodiode PD2, the floating diffusion FDpx, a floating diffusion FDmc2, the memory capacitance Cm2, and the parasitic capacitance of the micro bump MB. Also, during the second reset period RST2, at the time when the transfer control signal TXpd2 shifts to the LOW level, the exposure of the photodiode PD2 to light is initiated.

Subsequently, during the third reset period RST3 (between T62 and T63), HIGH pulses are given as the reset control signal RSpd, a reset control signal RSmc3, the transfer control signal TXpd3, the storage control signal TXmi3, and the read control signal TXmo3 to reset the photodiode PD3, the floating diffusion FDpx, a floating diffusion FDmc3, the memory capacitance Cm3, and the parasitic capacitance of the micro bump MB. Also, during the third reset period RST3, at the time when the transfer control signal TXpd3 shifts to the LOW level, the exposure of the photodiode PD3 to light is initiated.

Subsequently, during the fourth reset period RST4 (between T63 and T64), HIGH pulses are given as the reset control signal RSpd, a reset control signal RSmc4, the transfer control signal TXpd4, the storage control signal TXmi4, and the read control signal TXmo4 to reset the photodiode PD4, the floating diffusion FDpx, a floating diffusion FDmc4, the memory capacitance Cm4, and the parasitic capacitance of the micro bump MB. Also, during the fourth reset period RST4, at the time when the transfer control signal TXpd4 shifts to the LOW level, the exposure of the photodiode PD 4 to light is initiated.

Subsequently, during the first exposure period EXP1 (between T64 and T65), each of the photodiodes PD1 to PD4 is exposed to light. Also, during the first exposure period EXP1, HIGH pulses are given as the reset control signal RSpd, the reset control signal RSmc1, the storage control signal TXmi1, and the read control signal TXmo1 to reset the floating diffusion FDpx, the floating diffusion FDmc1, and the memory capacitance Cm1.

Subsequently, during the first memory write period WRT1 (between T65 and T66), a HIGH pulse is given as the transfer control signal TXpd1 to transfer the charges generated in the photodiode PD1 to the floating diffusion FDpx and generate the first imaging signal voltage Vopx on the basis of the voltage in the floating diffusion FDpx. Also, during the first memory write period WRT1, a HIGH pulse is given as the storage control signal TXmi1 to store the charges generated on the basis of the first imaging signal voltage Vopx in the memory capacitance Cm1.

Subsequently, during the second exposure period EXP2 (between T66 and T67), each of the photodiodes PD2 to PD4 is exposed to light. Also, during the second exposure period EXP2, HIGH pulses are given as the reset control signal RSpd, the reset control signal RSmc2, the storage control signal TXmi2, and the read control signal TXmo2 to reset the floating diffusion FDpx, the floating diffusion FDmc2, and the memory capacitance Cm2.

Subsequently, during the second memory write period WRT2 (between T67 and T68), a HIGH pulse is given as the transfer control signal TXpd2 to transfer the charges generated in the photodiode PD2 to the floating diffusion FDpx and generate the first imaging signal voltage Vopx on the basis of the voltage in the floating diffusion FDpx. Also, during the second memory write period WRT2, a HIGH pulse is given as the storage control signal TXmi2 to store the charges generated on the basis of the first imaging signal voltage Vopx in the memory capacitance Cm2.

Subsequently, during the third exposure period EXP3 (between T68 and T69), both of the photodiodes PD3 and PD4 are exposed to light. Also, during the third exposure period EXP3, HIGH pulses are given as the reset control signal RSpd, the reset control signal RSmc3, the storage control signal TXmi3, and the read control signal TXmo3 to reset the floating diffusion FDpx, the floating diffusion FDmc3, and the memory capacitance Cm3.

Subsequently, during the third memory write period WRT3 (between T69 and T70), a HIGH pulse is given as the transfer control signal TXpd3 to transfer the charges generated in the photodiode PD3 to the floating diffusion FDpx and generate the first imaging signal voltage Vopx on the basis of the voltage in the floating diffusion FDpx. Also, during the third memory write period WRT3, a HIGH pulse is given as the storage control signal TXmi3 to store the charges generated on the basis of the first imaging signal voltage Vopx in the memory capacitance Cm3.

Subsequently, during the fourth exposure period EXP4 (between T70 and T71), the photodiode PD4 is exposed to light. Also, during the fourth exposure period EXP4, HIGH pulses are given as the reset control signal RSpd, the reset control signal RSmc4, the storage control signal TXmi4, and the read control signal TXmo4 to reset the floating diffusion FDpx, the floating diffusion FDmc4, and the memory capacitance Cm4.

Subsequently, during the fourth memory write period WRT4 (between T71 and T72), a HIGH pulse is given as the transfer control signal TXpd4 to transfer the charges generated in the photodiode PD4 to the floating diffusion FDpx and generate the first imaging signal voltage Vopx on the basis of the voltage in the floating diffusion FDpx. Also, during the fourth memory write period WRT4, a HIGH pulse is given as the storage control signal TXmi4 to store the charges generated on the basis of the first imaging signal voltage Vopx in the memory capacitance Cm4.

Subsequently, during the dark level read period DarkREAD (between T72 and T73), HIGH pulses are given as the reset control signals RSmc1 to RSmc4 to place the floating diffusions FDmc1 to FDmc4 at the reset voltages. Also, during the dark level read period DarkREAD, a HIGH pulse is given as the selection signal SEL to output the respective dark level signals generated by the amplification transistors 541 to 544 on the basis of the reset voltages to the bit lines BL1 to BL4.

Subsequently, during the imaging signal read period SigREAD (between T73 and T74), HIGH pulses are given as the read control signals TXmo1 to TXmo4 to transfer the charges stored in the memory capacitances Cm1 to Cm4 to the floating diffusions FDmc1 to FDmc4. In addition, the amplification transistors 541 to 544 output the second imaging signal voltages Vo1 to Vo4 on the basis of the voltages generated in the floating diffusions FDmc1 to FDmc4 on the basis of the transferred charges. Then, a HIGH pulse is given as the selection signal SEL to output the second imaging signal voltages Vo1 to Vo4 generated by the amplification transistors 541 to 544 to the bit lines BL.

As described above, in the imaging element 15 according to Embodiment 7, in the light detection circuit 40a, the four photodiodes PD are provided for the one pair of the reset transistor 42 and the amplification transistor 43. Accordingly, in the imaging element 15 according to Embodiment 7, the number of the transistors corresponding to each one of the photodiodes can further be reduced than that in the imaging element 15 according to Embodiment 6. Also, in the imaging element 15 according to Embodiment 7, by providing the amplification transistor 54 and the bit line BL for each one of the memory capacitances Cm, it is possible to simultaneously read the plurality of dark level signals and the plurality of imaging signals and increase the speeds of the operations.

### Embodiment 8

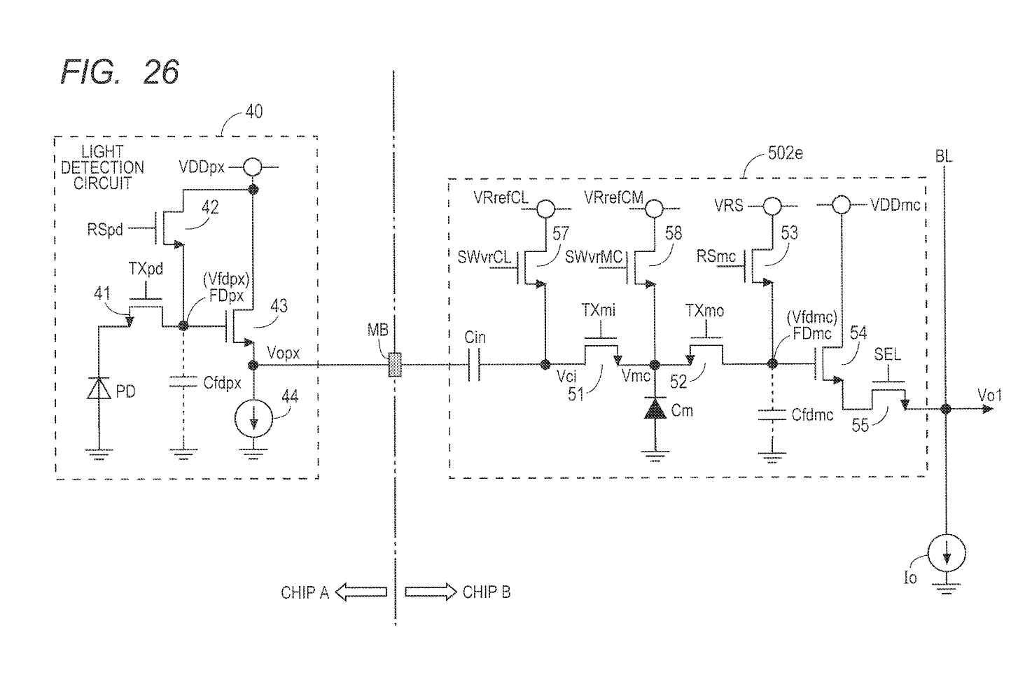

In Embodiment 8, a description will be given of an example in which, for the light detection circuit 40, a pixel value storage circuit 502e as a modification of the pixel value storage circuit 502 is provided. FIG. 26 shows a circuit diagram illustrating the light detection circuit 40 and the pixel value storage circuit 502e in the imaging element 15 according to Embodiment 8. Note that, in the description of Embodiment 8, the same components as those described in Embodiments 1 to 3 are denoted by the same reference numerals as used in Embodiments 1 to 3 and a description thereof is omitted.

As shown in FIG. 26, in the pixel value storage circuit 502e, a reset voltage VRS independent of the storage circuit power supply voltage VDDmc is given as a voltage to be given to the drain of the reset transistor 53 of the pixel value storage circuit 502. The pixel value storage circuit 502e is obtained by adding the reset transistor 57 and a reset transistor 58 to the pixel value storage circuit 50. The reset transistor 57 has a source coupled to the wire coupling the coupling capacitance Ci to the input transfer transistor 51, a drain to which a coupling capacitance reset voltage VRefCL is given, and a gate to which the coupling capacitance reset control signal SWvrCL is given. The reset transistor 58 is coupled to the other end of the memory capacitance Cm and has a drain to which a memory capacitance reset voltage VRefCN is given and a gate to which a memory capacitance reset control signal SWvrCN is given.

That is, in the pixel value storage circuit 502e according to Embodiment 8, the floating diffusion FDmc, the memory capacitance Cm, and the coupling capacitance Cin are reset with the reset voltages independent of each other.

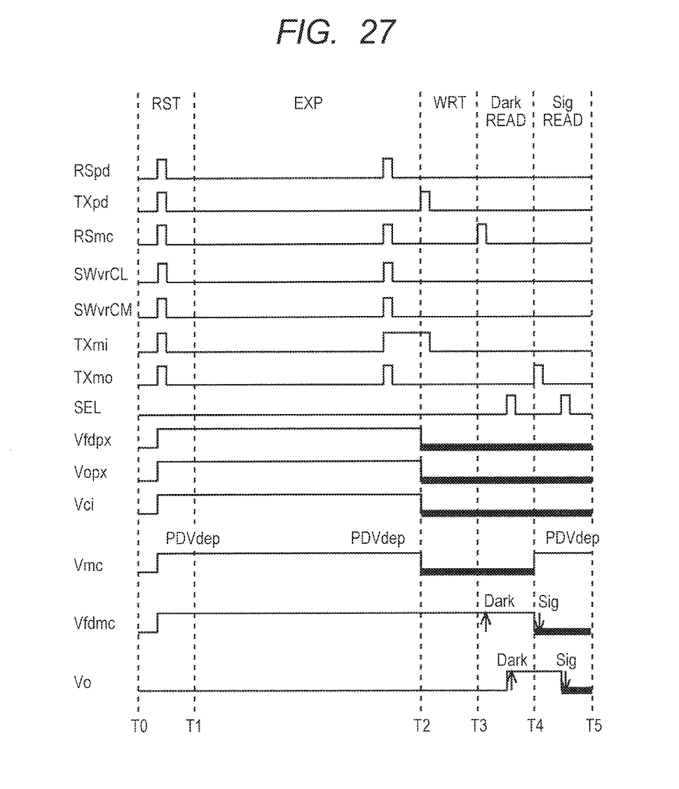

A description will be given of the operations of the light detection circuit 40 and the pixel value storage circuit 502e in the imaging element 15 according to Embodiment 8. FIG. 27 shows a timing chart illustrating the operations of the light detection circuit 40 and the pixel value storage circuit 502e in the imaging element 15 according to Embodiment 8. The timing chart shown in FIG. 27 is obtained by causing the light detection circuit 40 and the pixel value storage circuit 502e according to Embodiment 8 to perform the same operations as those of the light detection circuit 40 and the pixel value storage circuit 50 according to Embodiment 1 shown in FIG. 4.

As shown in FIG. 27, in the operations of the light detection circuit 40 and the pixel value storage circuit 502e according to Embodiment 8, the coupling capacitance reset control signal SWvrCL and the memory capacitance reset control signal SWvrCM are added. The coupling capacitance reset control signal SWvrCL and the memory capacitance reset control signal SWvrCM are generated at the same timing when the reset control signal RSpd is generated so as to generate HIGH pulses. Accordingly, in the pixel value storage circuit 502e according to Embodiment 8, the floating diffusion FDmc, the memory capacitance Cm, and the coupling capacitance Cin are reset with the corresponding voltages before charges are transferred to the memory capacitance Cm.

As described above, in the pixel value storage circuit 502e according to Embodiment 8, by resetting the floating diffusion FDmc, the memory capacitance Cm, and the coupling capacitance Cin with the reset voltages independent of each other, it is possible to reduce the time required for resetting. Also, in the pixel value storage circuit 502e according to Embodiment 8, by resetting the floating diffusion FDmc, the memory capacitance Cm, and the coupling capacitance Cin with the reset voltages independent of each other, it is possible to reset the individual regions with optimum reset voltages.

### Embodiment 9

In Embodiment 9, a description will be given of an example in which, for the light detection circuit 40, the pixel value storage circuit 502b described in Embodiment 5 is provided. FIG. shows a circuit diagram illustrating the light detection circuit 40 and the pixel value storage circuit 502b in the imaging element 15 according to Embodiment 9. Note that, in the description of Embodiment 9, the same components as those described in Embodiments 1 to 3 and 5 are denoted by the same reference numerals as used in Embodiments 1 to 3 and 5 and a description thereof is omitted.

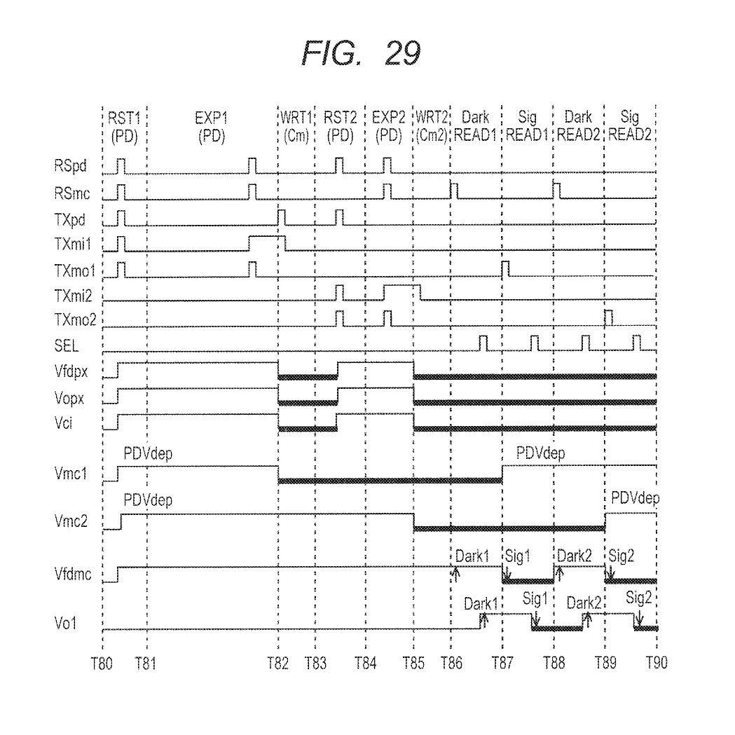

In the imaging element 15 according to Embodiment 9, by providing the pixel value storage circuit 502b described in Embodiment 5 for the light detection circuit 40 described in Embodiment 1, the two imaging signals obtained by exposing the photodiode PD to light for different periods of time are stored in the pixel value storage circuit 502b. A detailed description will be given of the operations of the light detection circuit 40 and the pixel value storage circuit 502b according to Embodiment 9. FIG. 29 shows a timing chart illustrating the operations of the light detection circuit 40 and the pixel value storage circuit 502b in the imaging element 15 according to Embodiment 9.

As shown in FIG. 29, during the first reset period RST1 (between T80 and T81), HIGH pulses are given as the reset control signal RSpd, the reset control signal RSmc, the transfer control signal TXpd1, the storage control signal TXmi1, and the read control signal TXmo1 to reset the photodiode PD, the floating diffusion FDpx, the floating diffusion FDmc, the memory capacitance Cm1, and the parasitic capacitance of the micro bump MB. Also, during the first reset period RST1, at the time when the transfer control signal TXpd shifts to the LOW level, the exposure of the photodiode PD to light is initiated.

Subsequently, during the first exposure period EXP1 (between T81 and T82), the photodiode PD is exposed to light. Also, during the first exposure period EXP1, HIGH pulses are given as the reset control signal RSpd, the reset control signal RSmc, the storage control signal TXmi1, and the read control signal TXmo1 to reset the floating diffusion FDpx, the floating diffusion FDmc, and the memory capacitance Cm1.

Subsequently, during the first memory write period WRT1 (between T82 and T83), a HIGH pulse is given as the transfer control signal TXpd to transfer the charges generated in the photodiode PD to the floating diffusion FDpx and generate the first imaging signal voltage Vopx on the basis of the voltage in the floating diffusion FDpx. Also, during the first memory write period WRT1, a HIGH pulse is given as the storage control signal TXmi1 to store the charges generated on the basis of the first imaging signal voltage Vopx in the memory capacitance Cm1.

Subsequently, during the second reset period RST2 (between T83 and T84), HIGH pulses are given as the reset control signal RSpd, the reset control signal RSmc, the transfer control signal TXpd, the storage control signal TXmi2, and the read control signal TXmo2 to reset the photodiode PD, the floating diffusion FDpx, the floating diffusion FDmc, the memory capacitance Cm2, and the parasitic capacitance of the micro bump MB. Also, during the second reset period RST2, at the time when the transfer control signal TXpd shifts to the LOW level, the exposure of the photodiode PD to light is initiated.

Subsequently, during the second exposure period EXP2 (between T84 and T85), the photodiode PD is exposed to light. The length of the second exposure period EXP2 is set shorter than the first exposure period EXP1. Also, during the second exposure period EXP2, HIGH pulses are given as the reset control signal RSpd, the reset control signal RSmc, the storage control signal TXmi2, and the read control signal TXmo2 to reset the floating diffusion FDpx, the floating diffusion FDmc, and the memory capacitance Cm2.

Subsequently, during the second memory write period WRT2 (between T85 and T86), a HIGH pulse is given as the transfer control signal TXpd to transfer the charges generated in the photodiode PD to the floating diffusion FDpx and generate the first imaging signal voltage Vopx on the basis of the voltage in the floating diffusion FDpx. Also, during the second memory write period WRT2, a HIGH pulse is given as the storage control signal TXmi2 to store the charges generated on the basis of the first imaging signal voltage Vopx in the memory capacitance Cm2.

Subsequently, during the first dark level read period DarkREAD1 (between T86 and T87), a HIGH pulse is given as the reset control signal RSmc to place the floating diffusion FDmc at the reset voltage. Also, during the first dark level read period DarkREAD1, a HIGH pulse is given as the selection signal SEL to output the dark level signal generated by the amplification transistor 54 on the basis of the reset voltage to the bit line BL.

Subsequently, during the first imaging signal read period SigREAD1 (between T87 and T88), a HIGH pulse is given as the read control signal TXmo1 to transfer the charges stored in the memory capacitance Cm1 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during the second dark level read period DarkREAD2 (between T88 and T89), a HIGH pulse is given as the reset control signal RSmc to place the floating diffusion FDmc at the reset voltage. Also, during the second dark level read period DarkREAD2, a HIGH pulse is given as the selection signal SEL to output the dark level signal generated by the amplification transistor 54 on the basis of the reset voltage to the bit line BL.

Subsequently, during the second imaging signal read period SigREAD2 (between T89 and T90), a HIGH pulse is given as the read control signal TXmo2 to transfer the charges stored in the memory capacitance Cm2 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

As described above, in the imaging element 15 according to Embodiment 9, the two imaging signals obtained during the exposure periods of different lengths are stored in the pixel value storage circuit 502b. The pixel value storage circuit 502b outputs the two stored imaging signals at individual timings. In the imaging element 15 according to Embodiment 9, the two imaging signals obtained during the exposure periods of different lengths are combined to generate one pixel value. By thus combining the two imaging signals obtained during the exposure periods of different lengths to generate the one pixel value, in the imaging element 15 according to Embodiment 9, the pixel value having a wide dynamic range can be obtained. For example, by generating a pixel value having high clarity for a portion with low brightness from the imaging signal obtained during the longer exposure period and generating a pixel value having high clarity for a portion having high brightness from the imaging signal obtained during the shorter exposure period, it is possible to widen the dynamic range of the brightness of the entire image.

### Embodiment 10

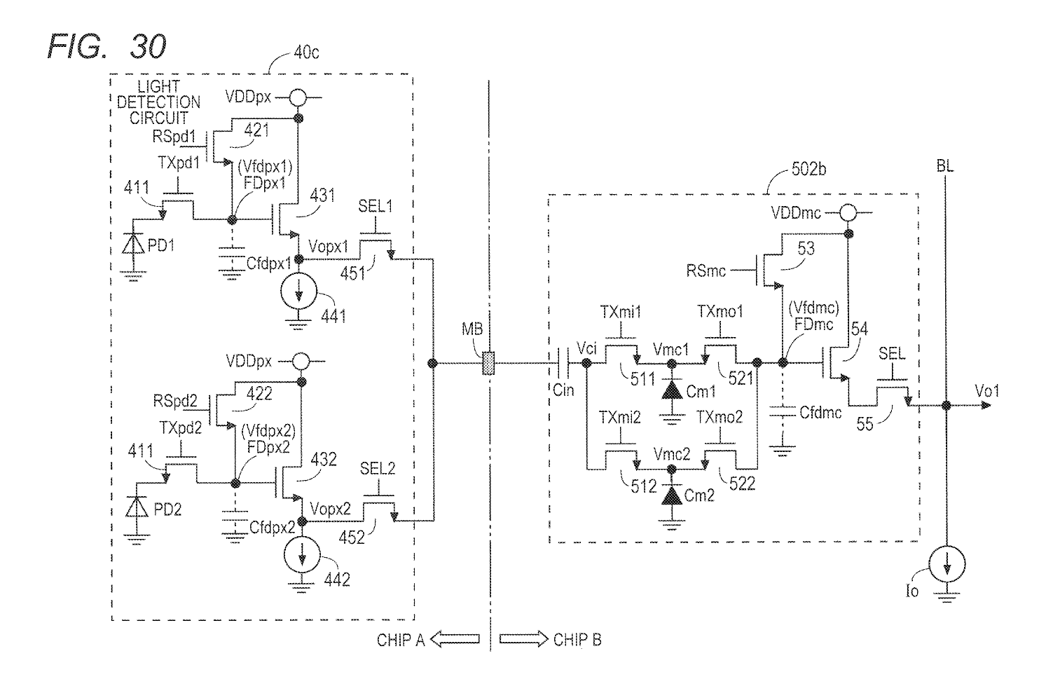

In Embodiment 10, a description will be given of an example in which, for the pixel value storage circuit 502b described in Embodiment 5, a light detection circuit 40c as a modification of the light detection circuit 40 is provided. FIG. 30 shows a circuit diagram illustrating the light detection circuit 40c and the pixel value storage circuit 502b in the imaging element 15 according to Embodiment 10. Note that, in the description of Embodiment 10, the same components as those described in Embodiments 1 to 3 and 5 are denoted by the same reference numerals as used in Embodiments 1 to 3 and 5 and a description thereof is omitted.

As shown in FIG. 30, the light detection circuit 40c includes the two light detection circuits 40 according to Embodiment 1 and transmits the first imaging signals output from the two light detection circuits 40 to the pixel value storage circuit 502b via the one micro bump MB.

Specifically, the light detection circuit 40c includes a first light detection circuit and a second light detection circuit. The first light detection circuit has the photodiode PD1, the transfer transistor 411, a reset transistor 421, an amplification transistor 431, a constant current supply 441, and a selection transistor 451. The second light detection circuit has the photodiode PD2, the transfer transistor 412, a reset transistor 422, an amplification transistor 432, a constant current supply 442, and the selection transistor 451. Each of the light detection circuits gives the first imaging signal to the micro bump via the selection transistor. Note that the coupling relations between the photodiode, the transfer transistor, the reset transistor, the amplification transistor, and the constant current supply in each of the light detection circuits are the same as those in the light detection circuit 40.

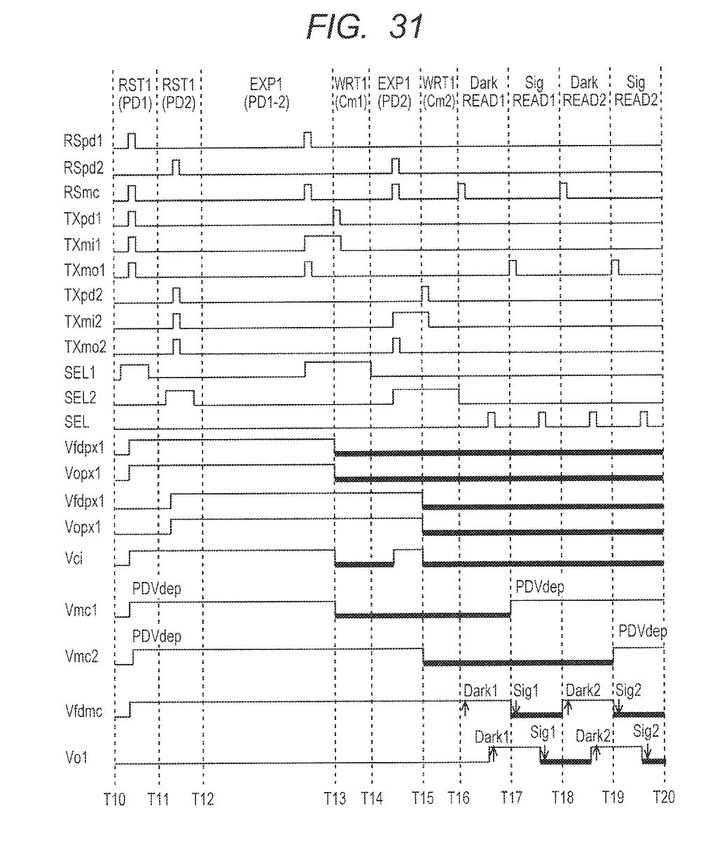

Subsequently, a description will be given of the operations of the light detection circuit 40c and the pixel value storage circuit 502b in the imaging element 15 according to Embodiment 10. FIG. 31 shows a timing chart illustrating the operations of the light detection circuit 40c and the pixel value storage circuit 502b in the imaging element 15 according to Embodiment 10. In the example shown in FIG. 31, the light detection circuit 40c and the pixel value storage circuit 502b according to Embodiment 10 are caused to perform the same operations as those of the light detection circuit 40a and the pixel value storage circuit 502b according to Embodiment 5 shown in FIG. 21.

As shown in FIG. 31, the operations of the light detection circuit 40c and the pixel value storage circuit 502b in the imaging element 15 according to Embodiment 10 are different from the similar operations of the light detection circuit 40a and the pixel value storage circuit 502b according to Embodiment 5 in that, as the reset control signal RSpd, a reset control signal RSpd1 corresponding to the first light detection circuit and a reset control signal RSpd2 corresponding to the second light detection circuit are used. Also, in the operations of the light detection circuit 40c and the pixel value storage circuit 502b in the imaging element 15 according to Embodiment 10, the selection signal SEL1 and a selection signal SEL2 which correspond to the selection transistor 451 and a selection transistor 452 are used.

As shown in FIG. 31, during the first reset period RST1 (between T10 and T11), HIGH pulses are given as the reset control signal RSpd1, the reset control signal RSmc, the transfer control signal TXpd1, the selection signal SEL1, the storage control signal TXmi1, and the read control signal TXmo1 to reset the photodiode PD1, the floating diffusion FDpx, the floating diffusion FDmc, the memory capacitance Cm1, and the parasitic capacitance of the micro bump MB. Note that the HIGH period of the selection signal SEL1 is set longer than those of the other pulse signals. Also, during the first reset period RS1, at the time when the transfer control signal TXpd1 shifts to the LOW level, the exposure of the photodiode PD1 to light is initiated.

Subsequently, during the second reset period RST2 (between T11 and T12), HIGH pulses are given as the reset control signal RSpd2, the reset control signal RSmc, the transfer control signal TXpd2, the selection signal SEL2, the storage control signal TXmi2, and the read control signal TXmo2 to reset the photodiode PD2, the floating diffusion FDpx, the floating diffusion FDmc, the memory capacitance Cm2, and the parasitic capacitance of the micro bump MB. Note that the HIGH period of the selection signal SEL2 is set longer than those of the other pulse signals. Also, during the second reset period RST2, at the time when the transfer control signal TXpd2 shifts to the LOW level, the exposure of the photodiode PD2 to light is initiated.

Subsequently, during the first exposure period EXP1 (between T12 and T13), each of the photodiodes PD1 and PD2 is exposed to light. During the first exposure period EXP1, HIGH pulses are given as the reset control signal RSpd1, the reset control signal RSmc, the selection signal SEL1, the storage control signal TXmi1, and the read control signal TXmo1 to reset the floating diffusion FDpx, the floating diffusion FDmc, and the memory capacitance Cm1. Note that the HIGH level of the selection signal SEL1 is maintained until the first memory write period WRT1 performed after the first exposure period EXP1 is ended.

Subsequently, during the first memory write period WRT1 (between T13 and T14), a HIGH pulse is given as the transfer control signal TXpd1 to transfer the charges generated in the photodiode PD1 to the floating diffusion FDpx and generate the first imaging signal voltage Vopx on the basis of the voltage in the floating diffusion FDpx. Also, during the first memory write period WRT1, a HIGH pulse is given as the storage control signal TXmi1 to store the charges generated on the basis of the first imaging signal voltage Vopx in the memory capacitance Cm1.

Subsequently, during the second exposure period EXP2 (between T14 and T15), the photodiode PD2 is exposed to light. During the second exposure period EXP2, HIGH pulses are given as the reset control signal RSpd2, the reset control signal RSmc, the selection signal SEL2, the storage control signal TXmi2, and the read control signal TXmo2 to reset the floating diffusion FDpx, the floating diffusion FDmc, and the memory capacitance Cm2. Note that the HIGH level of the selection signal SEL2 is maintained until the second memory write period WRT2 performed after the second exposure period EXP2 is ended.

Subsequently, during the second memory write period WRT2 (between T15 and T16), a HIGH pulse is given as the transfer control signal TXpd2 to transfer the charges generated in the photodiode PD2 to the floating diffusion FDpx and generate the first imaging signal voltage Vopx on the basis of the voltage in the floating diffusion FDpx. Also, during the second memory write period WRT2, a HIGH pulse is given as the storage control signal TXmi2 to store the charges generated on the basis of the first imaging signal voltage Vopx in the memory capacitance Cm2.

Subsequently, during the first dark level read period DarkREAD1 (between T16 and T17), a HIGH pulse is given as the reset control signal RSmc to place the floating diffusion FDmc at the reset voltage. Also, during the first dark level read period DarkREAD1, a HIGH pulse is given as the selection signal SEL to output the dark level signal generated by the amplification transistor 54 on the basis of the reset voltage to the bit line BL.

Subsequently, during the first imaging signal read period SigREAD1 (between T17 and T18), a HIGH pulse is given as the read control signal TXmo1 to transfer the charges stored in the memory capacitance Cm1 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

Subsequently, during the second dark level read period DarkREAD2 (between T18 and T19), a HIGH pulse is given as the reset control signal RSmc to place the floating diffusion FDmc at the reset voltage. Also, during the second dark level read period DarkREAD2, a HIGH pulse is given as the selection signal SEL to output the dark level signal generated by the amplification transistor 54 on the basis of the reset voltage to the bit line BL.

Subsequently, during the second imaging signal read period SigREAD2 (between T19 and T20), a HIGH pulse is given as the read control signal TXmo2 to transfer the charges stored in the memory capacitance Cm2 to the floating diffusion FDmc. In addition, the amplification transistor 54 outputs the second imaging signal voltage Vo1 on the basis of the voltage generated in the floating diffusion FDmc on the basis of the transferred charges. Then, a HIGH pulse is given as the selection signal SEL to output the second imaging signal voltage Vo1 generated by the amplification transistor 54 to the bit line BL.

As described above, in the imaging element 15 according to Embodiment 10, the selection transistors are coupled to the respective outputs of the first and second light detection circuits in the light detection circuit 40c such that the plurality of selection transistors are coupled to the one bump. In the combination of the light detection circuit 40a and the pixel value storage circuit 502b according to Embodiment 5 shown in FIG. 20, the plurality of photodiodes PD are coupled to the one amplification transistor, and therefore a resetting operation in the light detection circuit cannot independently be performed for each of the photodiodes. However, in the configuration according to Embodiment 10, an operation of resetting a pixel can be performed independently for each of the photodiodes. This can reduce the interval between the reading of the imaging signal for one of the pixels and resetting for the subsequent pixel. Accordingly, in the imaging element 15 according to Embodiment 10, the imaging signal can be read at a higher speed than in the imaging element 15 according to Embodiment 5.

### Embodiment 11

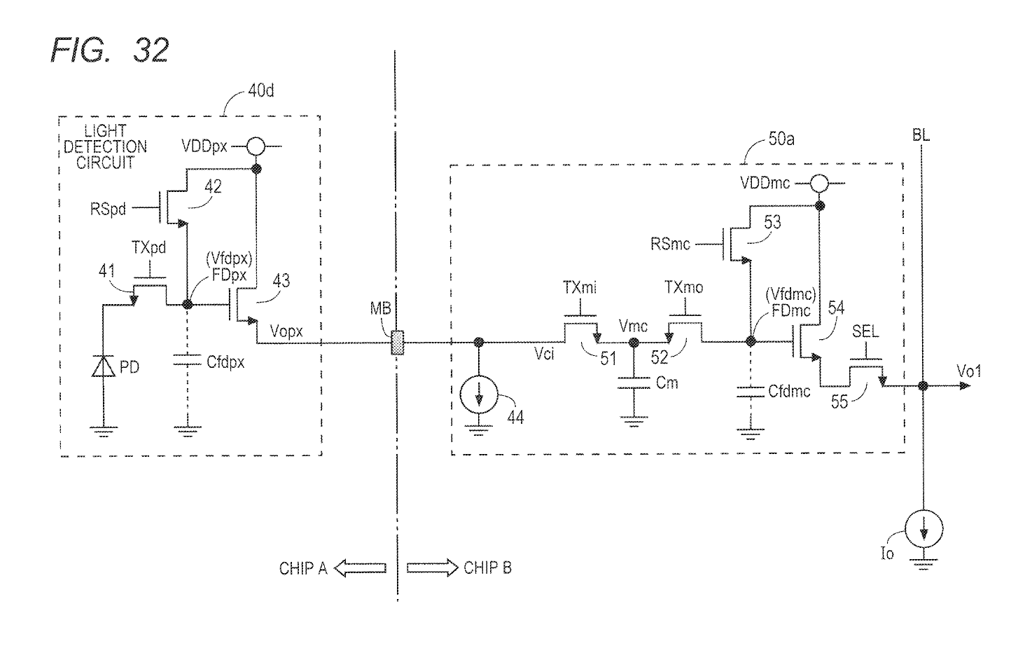

In Embodiment 11, a description will be given of an example in which the constant current supply 44 in the light detection circuit 40 is disposed in the pixel value storage circuit 50. FIG. 32 shows a circuit diagram illustrating a light detection circuit 40d and a pixel value storage circuit 50a in the imaging element 15 according to Embodiment 11. Note that, in the description of Embodiment 11, the same components as those described in Embodiment 1 are denoted by the same reference numerals as used in Embodiment 1 and a description thereof is omitted.

As shown in FIG. 32, the light detection circuit 40d according to Embodiment 11 is obtained by removing the constant current supply 44 from the light detection circuit 40 in Embodiment 1. On the other hand, the pixel value storage circuit 50a according to Embodiment 11 is obtained by adding the constant current supply 44 to the pixel value storage circuit 50 according to Embodiment 1. In the pixel value storage circuit 50a, the constant current supply 44 is provided between the wire connecting the coupling capacitance Gin to the micro bump MB and the grounding wire.

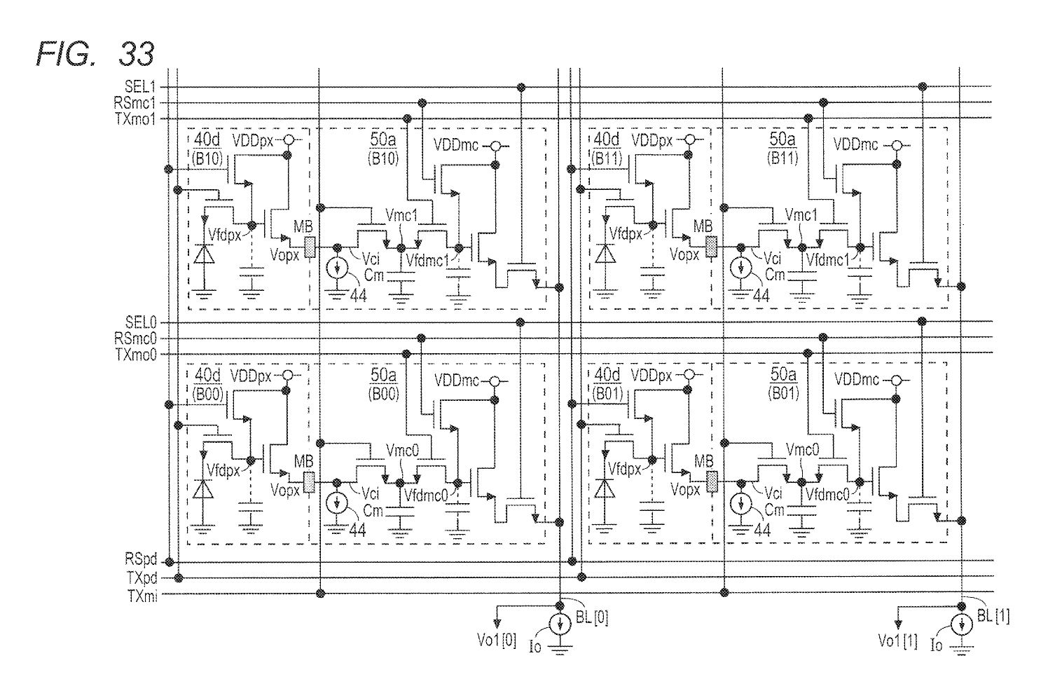

A description will be given herein of the locations of the constant current supplies 44 when a plurality of the light detection circuits 40d and a plurality of the pixel value storage circuits 50a are arranged. FIG. 33 shows a circuit diagram illustrating the state where the light detection circuits 40d and the pixel value storage circuits 50a in the imaging elements 15 according to Embodiment 11 are arranged in respective grid-like configurations. FIG. 33 is obtained by re-drawing the circuit diagram related to the imaging element 15 according to Embodiment 1 shown in FIG. 10 in accordance with a circuit layout in the imaging element 15 according to Embodiment 11.

As shown in FIG. 33, in the imaging element 15 according to Embodiment 11, each of the pixel value storage circuits 50a has the constant current supply 44 serving as a positive load on the source follower circuit of the light detection circuit 40b corresponding to each of the pixel value storage circuits.

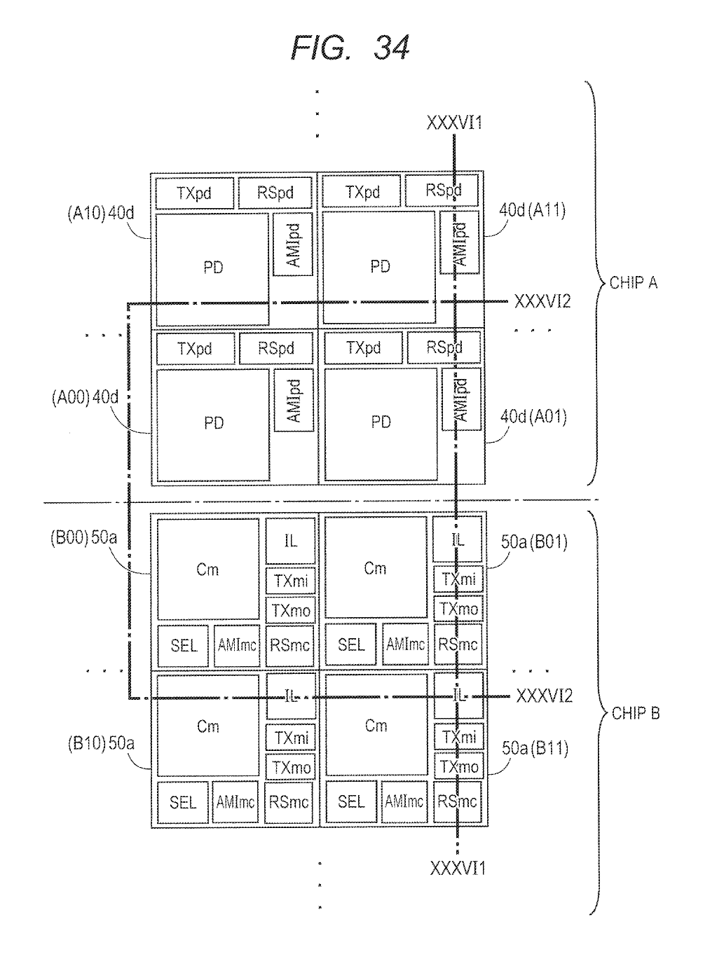

FIG. 34 shows a view illustrating an example of a layout of respective semiconductor substrates corresponding to the light detection circuits and the pixel value storage circuits which are shown in FIG. 33. As shown in FIG. 34, in the imaging element 15 according to Embodiment 11, the constant current supplies 44 are not disposed in the light detection circuits 40d disposed in the chip A, but are disposed in the pixel value storage circuits 50a in the chip B.

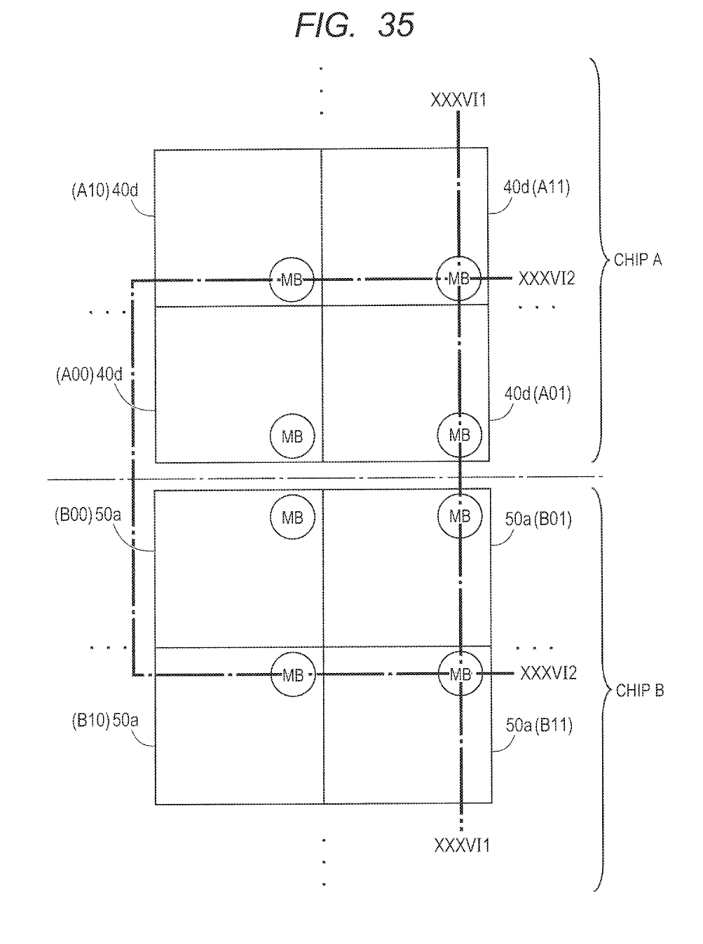

FIG. 35 shows a view illustrating an example of a layout of the micro bumps MB corresponding to the light detection circuits and the pixel value storage circuits which are shown in FIG. 33. As shown in FIG. 35, the arrangement of the micro bumps MB is substantially the same as the arrangement of the micro bumps MB in the imaging element 15 according to Embodiment 1 shown in FIG. 8.

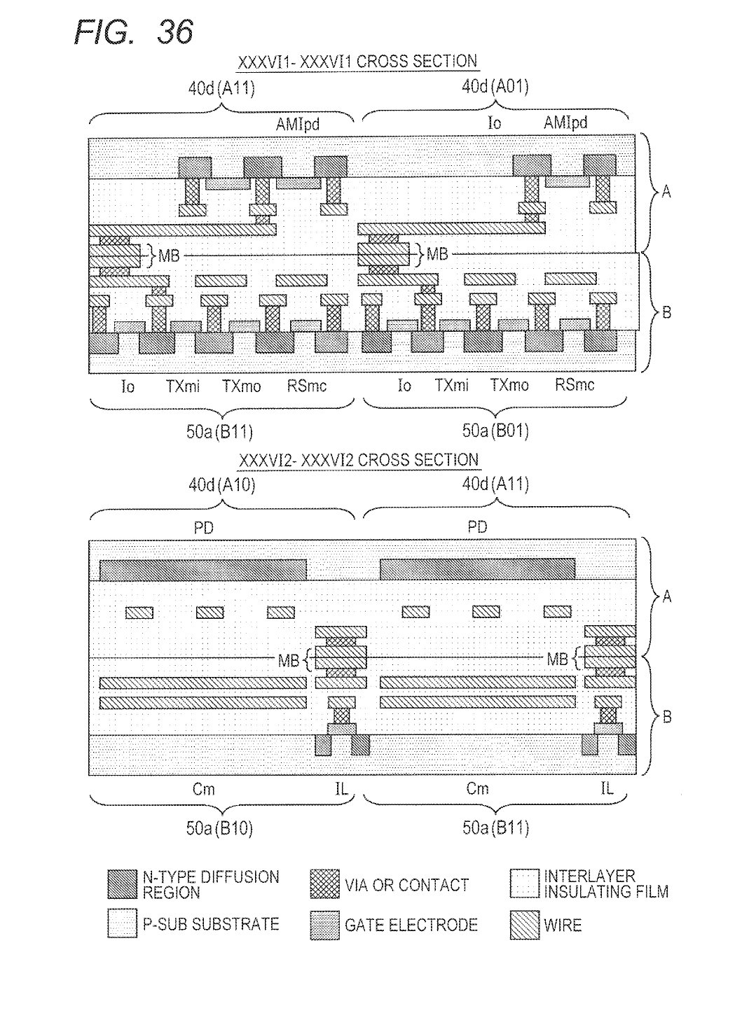

FIG. 36 shows a schematic diagram of the imaging element when the chips A and B are stacked in the imaging element 15 according to Embodiment 11. Note that the cross-sectional views shown in FIG. 36 are along the lines XXXVI1-XXXVI1 and XXXVI2-XXXVI2 shown in FIGS. 34 and 35. As shown in FIG. 36, in the imaging element 15 according to Embodiment 11, a constant current supply IL serving as the constant current supplies 44 is disposed in the layer below the micro bumps MB in the chip B.

By thus providing the constant current supplies 44 in the pixel value storage circuits 50a, it is possible to reduce the number of the elements included in each of the light detection circuits 40d. By thus reducing the number of the elements in the light detection circuit 40d, it is possible to increase the area of the photodiode PD or increase a metal aperture area. This can improve the sensitivity of the imaging element 15 according to Embodiment 11. This can also widen the dynamic range in the imaging element 15 according to Embodiment 11.

While the invention achieved by the present inventors has been specifically described heretofore on the basis of the embodiments thereof, the present invention is not limited to the already described embodiments. It will be appreciated that various changes and modifications can be made in the invention within the scope not departing from the gist thereof.

For example, the imaging element described in the foregoing embodiments can also be taken from the following viewpoint.

(Note 1)

An imaging element, including:

a first chip in which a plurality of light detection circuits are formed in a grid-like configuration so as to be exposed to light; and

a second chip in which a plurality of pixel value storage circuits that receive imaging signals output from the light detection circuits are formed and which is shielded from light,

in which each of the light detection circuits includes:

a photoelectric conversion element; and

a first source follower circuit which amplifies a voltage level corresponding to an amount of light received by the photoelectric conversion element to output a first imaging signal, and

in which each of the pixel value storage circuits of the second chip includes:

a pixel value storage capacitance;

an input transfer transistor which transfers the first imaging signal output from the light detection circuit to the pixel value storage capacitance; and

a second source follower circuit which amplifies a voltage generated on the basis of the first imaging signal stored in the pixel value storage capacitance to output a second imaging signal.

(Note 2)

In the imaging element according to Note 1,

the pixel value storage circuit includes:

a floating diffusion;

an output transfer transistor which transfers charges from the pixel value storage capacitance to the floating diffusion; and

an amplification transistor which amplifies, in the second source follower circuit, a voltage generated in the floating diffusion.

(Note 3)

An imaging element in which a plurality of light detection circuits are arranged in a grid-like configuration, the imaging element including:

a first light detection circuit; and

a second light detection circuit disposed in the same column as the first light detection circuit,

in which each of the first light detection circuit and the second light detection circuit includes:

a photoelectric conversion element;

a floating diffusion;

a transfer transistor provided between the photoelectric conversion element and the floating diffusion;

a reset transistor which gives a reset voltage to the floating diffusion in response to a reset signal;

an amplification transistor which outputs an imaging signal on the basis of a potential in the floating diffusion; and

a constant current supply which gives a load current to the amplification transistor,

in which the amplification transistor of the first light detection circuit outputs the imaging signal via an output terminal provided to correspond to the first light detection circuit, and

in which the amplification transistor of the second light detection circuit outputs the imaging signal via an output terminal provided to correspond to the second light detection circuit.

(Note 4)

An imaging element in which a plurality of light detection circuits are arranged in a grid-like configuration, the imaging element including:

a first light detection circuit; and

a second light detection circuit disposed in the same column as the first light detection circuit,

in which each of the first light detection circuit and the second light detection circuit includes:

a photoelectric conversion element;

a floating diffusion;

a transfer transistor provided between the photoelectric conversion element and the floating diffusion;

a reset transistor which gives a reset voltage to the floating diffusion in response to a reset signal; and

an amplification transistor which outputs an imaging signal on the basis of a potential in the floating diffusion,

in which the amplification transistor of the first light detection circuit functions as a source follower circuit using a load current given from another chip via a first output terminal provided to correspond to the first light detection circuit and outputs the imaging signal to the first output terminal, and

in which the amplification transistor of the second light detection circuit functions as a source follower circuit using the load current given from the other chip via a second output terminal provided to correspond to the second light detection circuit and outputs the imaging signal to the second output terminal.

What is claimed is:

1. An imaging element, comprising:
a first chip in which a plurality of light detection circuits are formed in a grid-like configuration; and
a second chip in which a plurality of pixel value storage circuits that receive imaging signals output from the light detection circuits are formed,
wherein each of the light detection circuits includes:
a photoelectric conversion element;
a first floating diffusion;
a transfer transistor provided between the photoelectric conversion element and the first floating diffusion;
a first reset transistor which gives a first reset voltage to the first floating diffusion in response to a first reset signal; and
a first amplification transistor which outputs a first imaging signal on the basis of a potential in the first floating diffusion, and
wherein each of the pixel value storage circuits of the second chip includes:
a pixel value storage capacitance having one end to which a grounding voltage is given;
a second floating diffusion;
an input transfer transistor having one end to which the first imaging signal is input and the other end coupled to the other end of the pixel value storage capacitance;
an output transfer transistor having one end coupled to the other end of the pixel value storage capacitance and the other end coupled to the second floating diffusion;
a second reset transistor which gives a second reset voltage to the second floating diffusion in response to a second reset signal; and
a second amplification transistor which outputs a second imaging signal on the basis of a potential in the second floating diffusion.

2. The imaging element according to claim 1,
wherein the pixel value storage capacitance is a junction capacitance of a diode having an anode to which the grounding voltage is given and a cathode coupled to the other end of the input transfer transistor and to the one end of the output transfer transistor.

3. The imaging element according to claim 1,
wherein the pixel value storage capacitance includes:
a first-conductivity-type semiconductor substrate to which the grounding voltage is given;
a second-conductivity-type first diffusion region formed in a layer above the first-conductivity-type semiconductor substrate; and
a first-conductivity-type second diffusion region formed in a layer above the first diffusion region, and
wherein the first diffusion region and the other end of the input transfer transistor are formed in a continuous integrated region, while the first diffusion region and the one end of the output transfer transistor are formed in a continuous integrated region.

4. The imaging element according to claim 1,
wherein the second chip has a coupling capacitance inserted in series between the input transfer transistor and an input terminal.

5. The imaging element according to claim 4, further comprising:
a third reset transistor located between the coupling capacitance and the input transfer transistor to give a third reset voltage in response to a third reset signal.

6. The imaging element according to claim 1,
wherein the second amplification transistor outputs the imaging signal to a bit line provided commonly for the pixel value storage circuits disposed in the same column via a selection transistor.

7. The imaging element according to claim 1,
wherein the first chip transfers the imaging signals resulting from simultaneous exposure of the photoelectric conversion elements of the light detection circuits to light to the pixel value storage capacitances of the corresponding pixel value storage circuits,
wherein the second chip has bit lines each provided commonly for the pixel value storage circuits disposed in the same column, and
wherein the pixel value storage circuits output the imaging signals stored in the pixel value storage capacitances to the corresponding bit lines on a per-row basis.

8. The imaging element according to claim 1,
wherein each of the light detection circuits has a plurality of pairs of the photoelectric conversion elements and the transfer transistors, and
wherein each of the pixel value storage circuits has the same number of sets of the pixel value storage capacitances, the input transfer transistors, and the output transfer transistors as the number of the pairs of the photoelectric conversion elements and the transfer transistors of the light detection circuit.

9. The imaging element according to claim 1,
wherein each of the light detection circuits has a plurality of pairs of the photoelectric conversion elements and the transfer transistors, and
wherein each of the pixel value storage circuits has the same number of sets of the pixel value storage capacitances, the input transfer transistors, the output transfer transistors, the second floating diffusions, the second reset transistors, and the second amplification transistors as the number of the pairs of the photoelectric conversion elements and the transfer transistors of the light detection circuit.

10. The imaging element according to claim 9,
wherein the second chip has a plurality of bit lines each provided commonly for the pixel value storage circuits disposed in the same column, and
wherein the bit lines respectively correspond to the second amplification transistors in the pixel value storage circuits.

11. The imaging element according to claim 1, further comprising:
a fourth reset transistor which gives a fourth reset voltage to the other end of each of the pixel value storage capacitances in response to a fourth reset signal.

12. The imaging element according to claim 1,
wherein each of the pixel value storage capacitances has a plurality of sets of the pixel value storage capacitances, the input transfer transistors, and the output transfer transistors.

13. The imaging element according to claim 1,
wherein each of the light detection circuits has a plurality of sets of the photoelectric conversion elements, the transfer transistors, the first floating diffusions, the first reset transistors, and the first amplification transistors, and
wherein each of the pixel value storage circuits has the same number of sets of the pixel value storage capacitances, the input transfer transistors, and the output transfer transistors as the number of pairs of the photoelectric conversion elements and the transfer transistors of the light detection circuit.

14. The imaging element according to claim 1,
wherein the second chip has a load current supply coupled between a source of the first amplification transistor and a grounding wire.

15. The imaging element according to claim 1,
wherein the light detection circuits formed in the first chip and the pixel value storage circuits formed in the second chip are coupled to each other via micro bumps.
